(19) United States
(12) Patent Application Publication
(10) Pub. No.: US 2012/0007208 A1
(43) Pub. Date: Jan. 12, 2012

(54) Semiconductor Devices and Methods of Manufacturing the Same

(76) Inventors: Hyun-Gi Kim, Hwaseong-si (KR); Yongchul Oh, Suwon-si (KR); Yoosang Hwang, Suwon-si (KR); Cheolho Baek, Yongin-si (KR); Hui-Jung Kim, Seongnam-si (KR); Young-Seung Cho, Yongin-si (KR)

(21) Appl. No.: 13/177,128

(22) Filed: Jul. 6, 2011

(30) Foreign Application Priority Data
Jul. 7, 2010 (KR) 10-2010-0065537

(51) Int. Cl. H01L 29/06; H01L 21/762

(52) U.S. Cl. 257/506; 438/430; 257/E21.546; 257/E29.02

(57) ABSTRACT

Semiconductor devices and methods of manufacturing the same are provided. The semiconductor devices may include first and second active patterns. The second active patterns may protrude from the first active patterns. The semiconductor devices may also include a device isolation pattern between each of the first active patterns. The semiconductor devices may further include a sidewall mask on the first active patterns and the second active patterns. The semiconductor devices may additionally include a buried conductive pattern on the device isolation pattern.

### CROSS-REFERENCE TO RELATED APPLICATIONS

This U.S. non-provisional patent application claims priority under 35 U.S.C. §119 of Korean Patent Application No. 10-2010-0065537, filed on Jul. 7, 2010, the disclosure of which is hereby incorporated by reference in its entirety.

### BACKGROUND

The present disclosure herein relates to semiconductor devices and methods of manufacturing the same.

DRAM structures including a transistor having a vertical channel and a bit line buried in a lower portion of the transistor have been proposed. When forming a buried bit line, a substrate may be etched using a photoresist pattern as an etching mask. However, because a line width may be narrowing, there may be a limit to performing a patterning process using a photoresist pattern.

### SUMMARY

Embodiments of the inventive concept may provide semiconductor devices. The semiconductor devices may include first active patterns extending in a direction. The semiconductor devices may also include second active patterns each having a pillar shape that protrudes from an upper portion of each of the first active patterns. The semiconductor devices may further include a device isolation pattern between each of the first active patterns. The semiconductor devices may additionally include a sidewall mask extending from a side surface of each of the first active patterns along a side surface of each of the second active patterns. The semiconductor devices may further include a buried conductive pattern on the device isolation pattern between the first active patterns and extending in the direction, one side surface of the buried conductive pattern being in contact with one of the first active patterns.

In some embodiments, the device isolation pattern may include a lower portion having a first width and an upper portion upwardly extending from one side of the lower portion and having a second width substantially smaller than the first width.

In some embodiments, a side surface of the buried conductive pattern that opposes the one side surface of the buried conductive pattern may be in contact with an upper portion of the device isolation pattern.

In some embodiments, the sidewall mask may include a first portion on ones of sidewalls of the first and second active patterns and a second portion on ones of opposing sidewalls of the first and second active patterns, and a thickness of the first portion may be substantially smaller than a thickness of the second portion.

In some embodiments, the first and second portions of the sidewall mask may be on opposing side surfaces of the buried conductive pattern.

In some embodiments, a central axis of a bottom surface of the buried conductive pattern may be offset from a central axis of a bottom surface of the device isolation pattern.

In some embodiments, a central axis of a bottom surface of the buried conductive pattern may be located at a same axis line as a central axis of a bottom surface of the device isolation pattern. The sidewall mask may include a third portion on ones of sidewalls of the first and second active patterns and a fourth portion on ones of opposing sidewalls of the first and second active patterns, and a thickness of the third portion may be substantially smaller than a thickness of the fourth portion.

In some embodiments, the third and fourth portions of the sidewall mask may be on opposing side surfaces of the buried conductive pattern.

In some embodiments, a width of the buried conductive pattern may be substantially greater than a width of the device isolation pattern.

Embodiments of the inventive concept may also provide methods of manufacturing semiconductor devices. The methods may include forming preliminary first active patterns extending in a first direction on a substrate. The methods may also include forming a sidewall mask on upper sidewalls of the preliminary first active patterns. The methods may further include forming first active patterns extending in a first direction and second active patterns each having a pillar shape on the first active patterns by partly etching the preliminary first active patterns in a second direction different from the first direction. The methods may additionally include forming a device isolation pattern between the first active patterns under the sidewall mask. The methods may further include forming a buried conductive pattern on the device isolation pattern by an etching process using the sidewall mask, one side surface of the buried conductive pattern being in contact with the first active pattern.

In some embodiments, while partly etching the preliminary first active patterns in the second direction, the sidewall mask may substantially remain on the sidewalls of the first and second active patterns.

In some embodiments, forming the buried conductive pattern may include forming first and second spacers on opposing sidewalls of the preliminary first active patterns. Forming the buried conductive pattern may also include removing the first spacer. Forming the buried conductive pattern may further include forming the first active patterns and a trench by etching the substrate using the second spacer as an etching mask. Forming the buried conductive pattern may additionally include forming first patterns on opposing sidewalls of the first active patterns. Forming the buried conductive pattern may also include forming a preliminary device isolation pattern burying the trench. Forming the buried conductive pattern may further include removing the second spacer. Forming the buried conductive pattern may additionally include forming the device isolation pattern by etching the first active patterns and a preliminary device isolation pattern using the first patterns as an etching mask. Forming the buried conductive pattern may also include forming the buried conductive pattern in an opening defined by the device isolation pattern and the first active patterns.

In some embodiments, removing the first spacer may include forming a sacrificial layer exposing the first spacer while burying a space between the preliminary first active patterns on which the first and second spacers are formed. Removing the first spacer may also include removing the exposed first spacer, where the first and second spacers and the sacrificial layer may be formed from material having a different etching selectivity with respect to an etching solution.

In some embodiments, removing the first spacer may include, after forming the first and second spacers, making the first and second spacers have a different etching selectivity from each other with respect to an etching solution by implanting a first impurity into the first spacer and a second impurity into the second spacer. Removing the first spacer may also include removing the first spacer using the etching solution used in etching the first active patterns.

In some embodiments, forming the sidewall mask may include forming first and second parts of the sidewall mask on opposing sidewalls of the preliminary first active patterns, where a thickness of the first part of the sidewall mask may be substantially smaller than a thickness of the second part of the sidewall mask.

Embodiments of the inventive concept may further provide semiconductor devices that include first and second active patterns, the second active patterns protruding from the first active patterns. The semiconductor devices may also include a sidewall mask having first and second portions on opposing sidewalls of the first active patterns and on opposing sidewalls of the second active patterns, the first portion of the sidewall mask having a plurality of layers and having a greater width than the second portion of the sidewall mask. The semiconductor devices may further include a device isolation pattern between the sidewalls of the first active patterns. The semiconductor devices may additionally include a buried conductive pattern on the device isolation pattern. The semiconductor devices may further include an insulating layer on the buried conductive pattern and between the first and second portions of the sidewall mask.

In some embodiments, at least a portion of the device isolation pattern may be between opposing sidewalls of an oxide pattern.

In some embodiments, the first portion of the sidewall mask may include a layer that the second portion of the sidewall mask does not include.

In some embodiments, a protruding portion of the device isolation pattern may protrude along one sidewall of the buried conductive pattern, and the protruding portion of the device isolation pattern may have a width that is substantially aligned with and substantially equal to a width of one of the layers of the first portion of the sidewall mask.

In some embodiments, at least a portion of the buried conductive pattern may be recessed within the sidewall mask.

### BRIEF DESCRIPTION OF THE FIGURES

The foregoing and other features and advantages of the disclosure will become more apparent by describing in detail exemplary embodiments thereof with reference to the following figures. In the figures:

FIGS. 1A through 1V are perspective views illustrating a method of manufacturing a semiconductor device according to some embodiments of the inventive concept.

FIGS. 2A and 2B are perspective views illustrating a method of manufacturing a semiconductor device according to some embodiments of the inventive concept.

FIGS. 3A through 3K are perspective views illustrating a method of manufacturing a semiconductor device according to some embodiments of the inventive concept.

FIG. 4A is a block diagram illustrating a system including a memory according to some embodiments of the inventive concept.

FIG. 4B is a block diagram illustrating an information processing system including a memory according to some embodiments of the inventive concept.

### DETAILED DESCRIPTION OF EXAMPLE EMBODIMENTS

Example embodiments are described below with reference to the accompanying drawings. Many different forms and embodiments are possible without deviating from the spirit and teachings of this disclosure and so the disclosure should not be construed as limited to the example embodiments set forth herein. Rather, these example embodiments are provided so that this disclosure will be thorough and complete, and will convey the scope of the disclosure to those skilled in the art. In the drawings, the sizes and relative sizes of layers and regions may be exaggerated for clarity. Like reference numbers refer to like elements throughout.

Example embodiments are described herein with reference to cross-section illustrations that are schematic illustrations of idealized example embodiments (and intermediate structures). As such, variations from the shapes of the illustrations as a result, for example, of manufacturing techniques and/or tolerances, are to be expected. Thus, example embodiments may not be construed as limited to the particular shapes of regions illustrated herein but may be construed to include deviations in shapes that result, for example, from manufacturing.

The terminology used herein is for the purpose of describing particular embodiments only and is not intended to be limiting of the embodiments. As used herein, the singular forms “a”, “an,” and “the” are intended to include the plural forms as well, unless the context clearly indicates otherwise. It will be further understood that the terms “comprises,” “comprising,” “includes,” and/or “including,” when used herein, specify the presence of stated features, steps, operations, elements, and/or components, but do not preclude the presence or addition of one or more other features, steps, operations, elements, components, and/or groups thereof. It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein the term “and/or” includes any and all combinations of one or more of the associated listed items.

It will be understood that, although the terms first, second, etc, may be used herein to describe various elements, these elements should not be limited by these terms. These terms are only used to distinguish one element from another. Thus, a first element could be termed a second element without departing from the teachings of the present embodiments.

Unless otherwise defined, all terms (including technical and scientific terms) used herein have the same meaning as commonly understood by one of ordinary skill in the art to which these embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

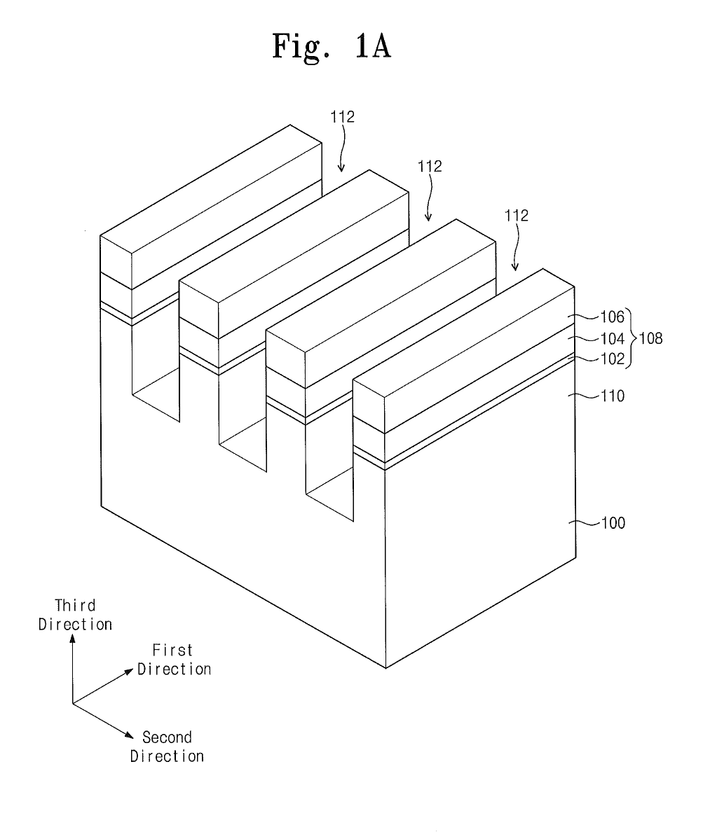

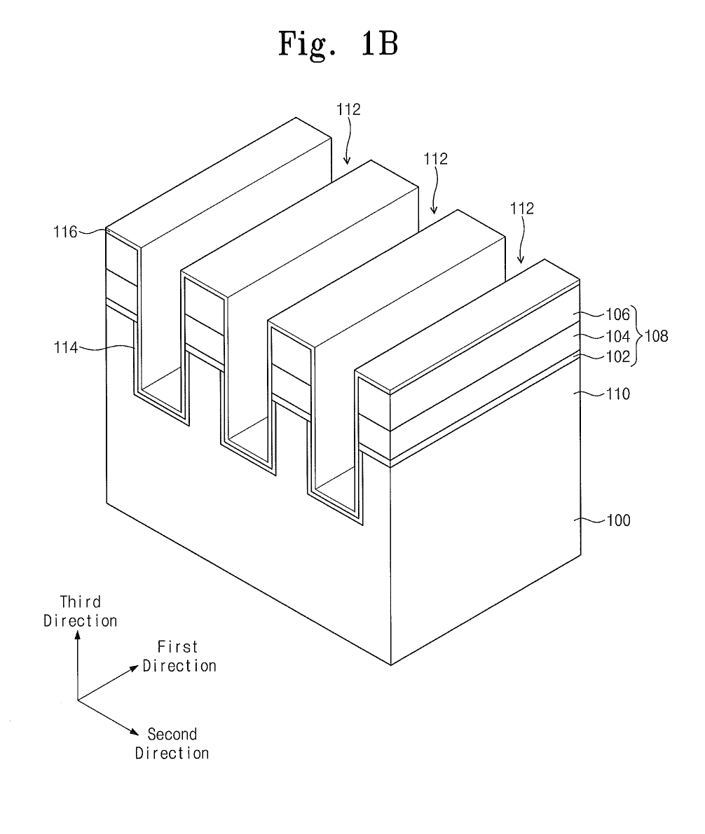

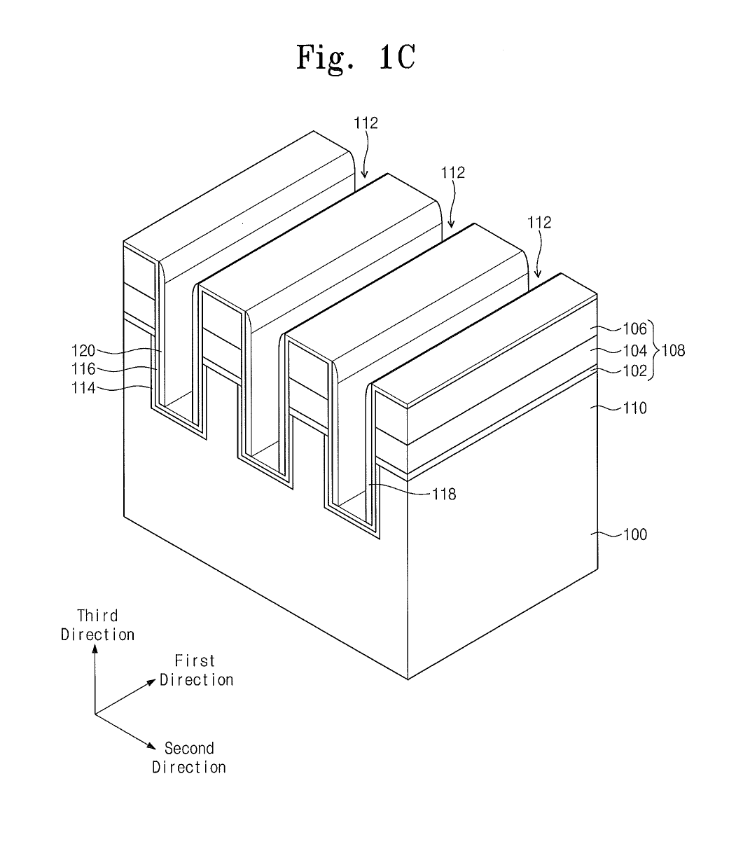

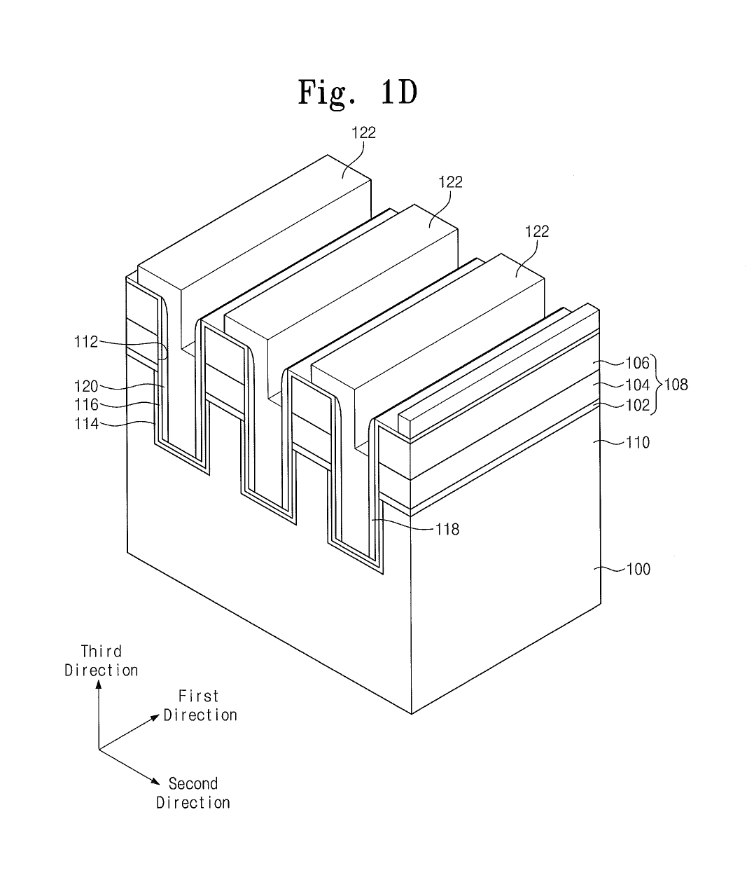

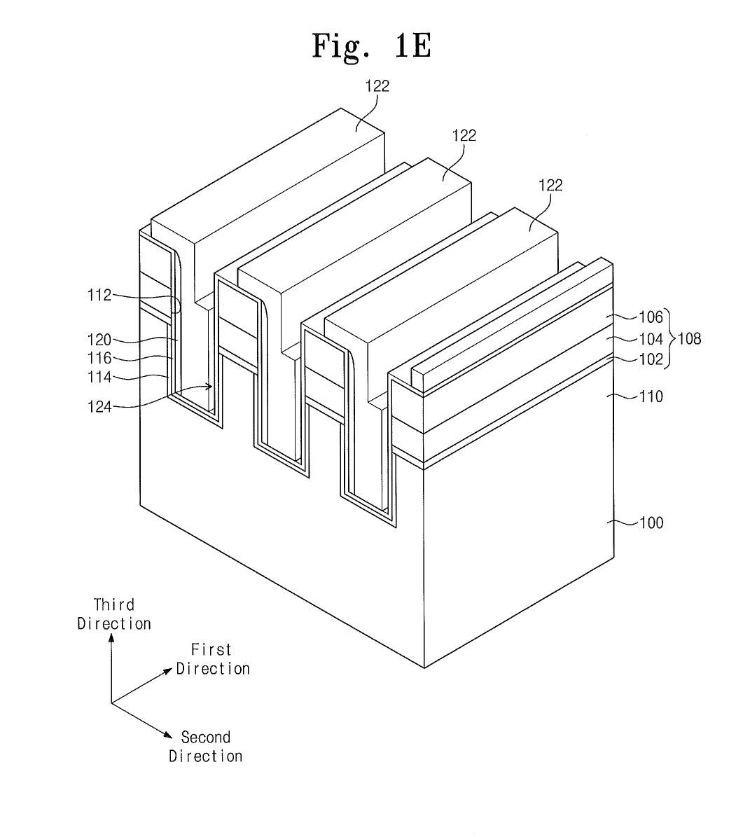

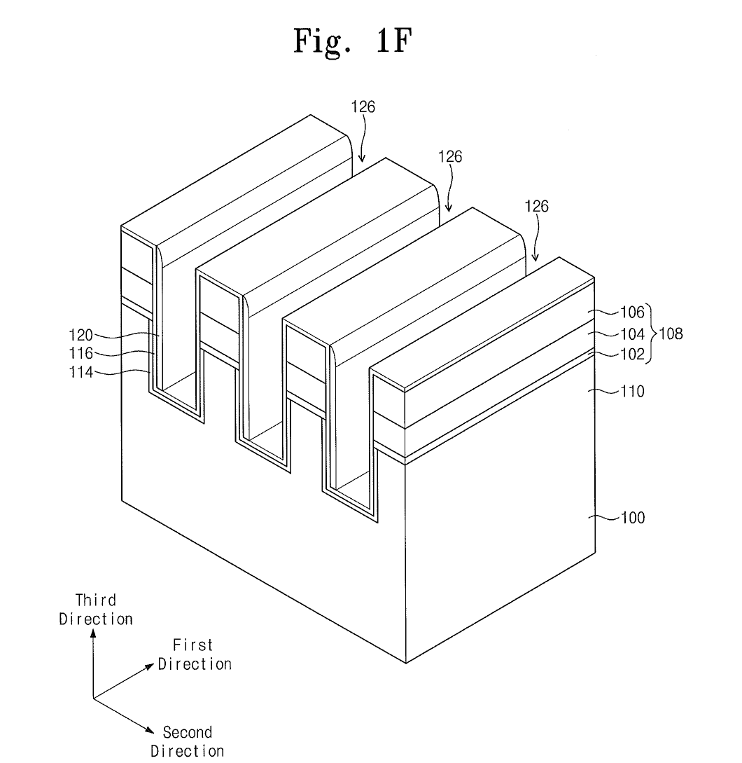

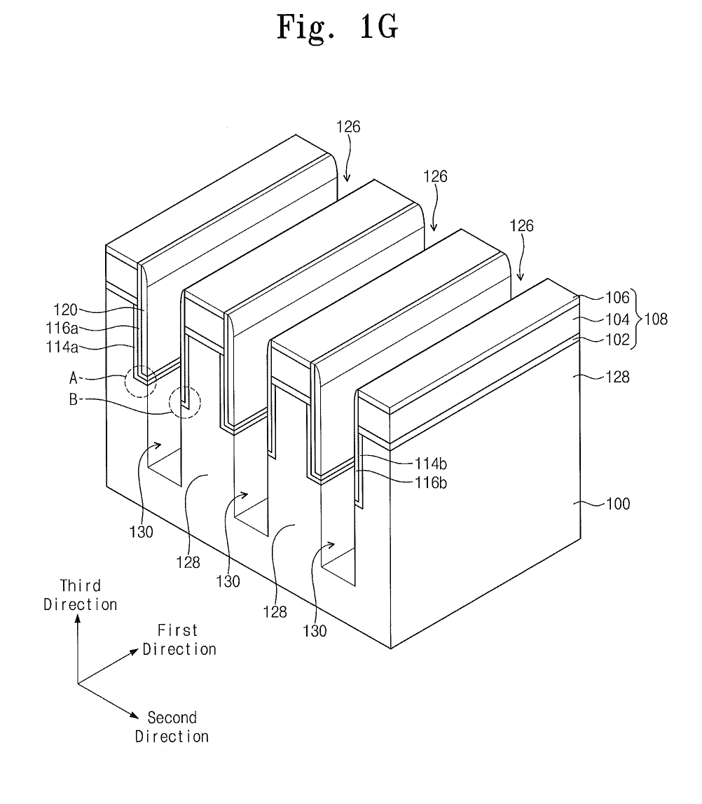

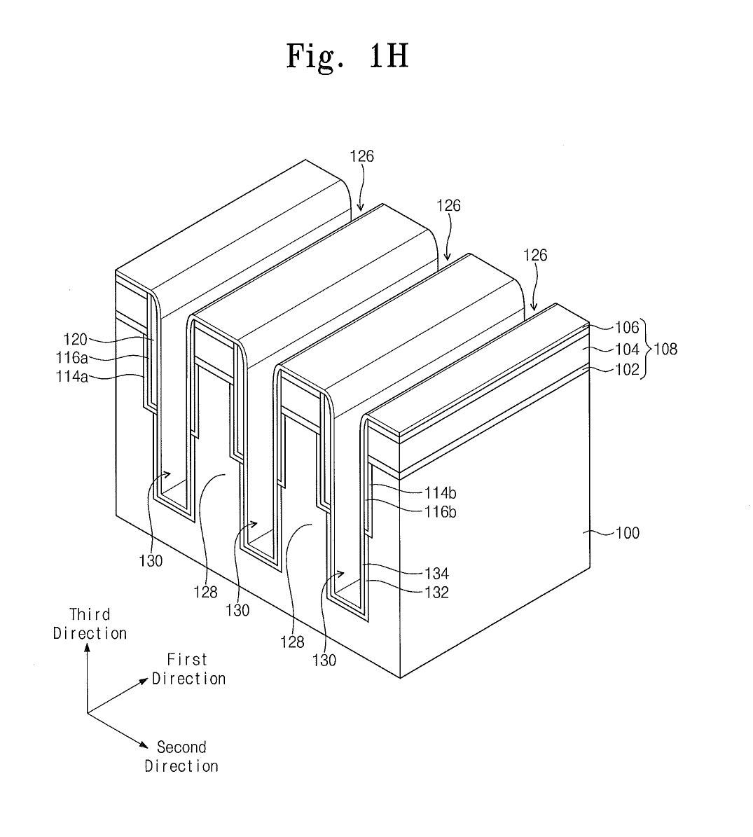

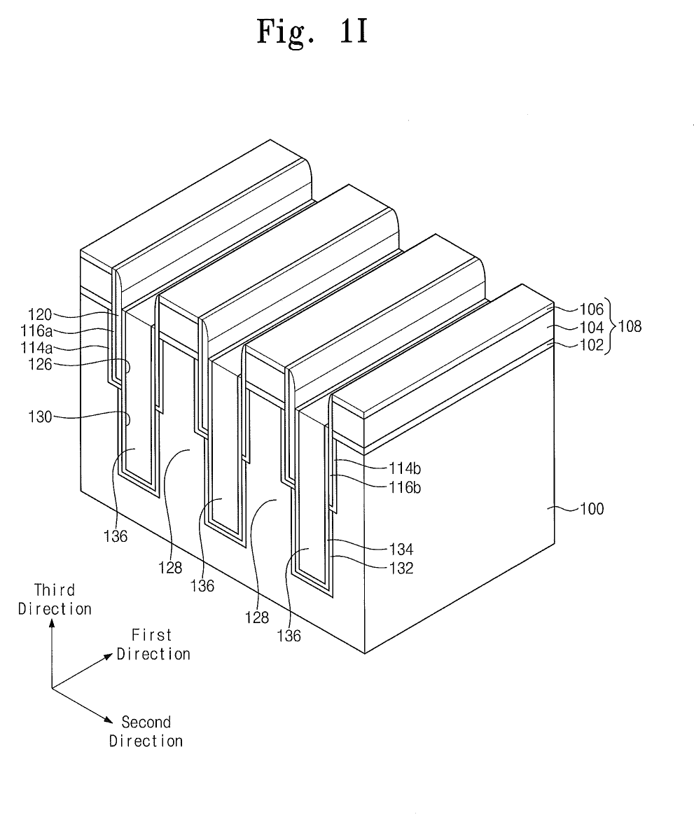

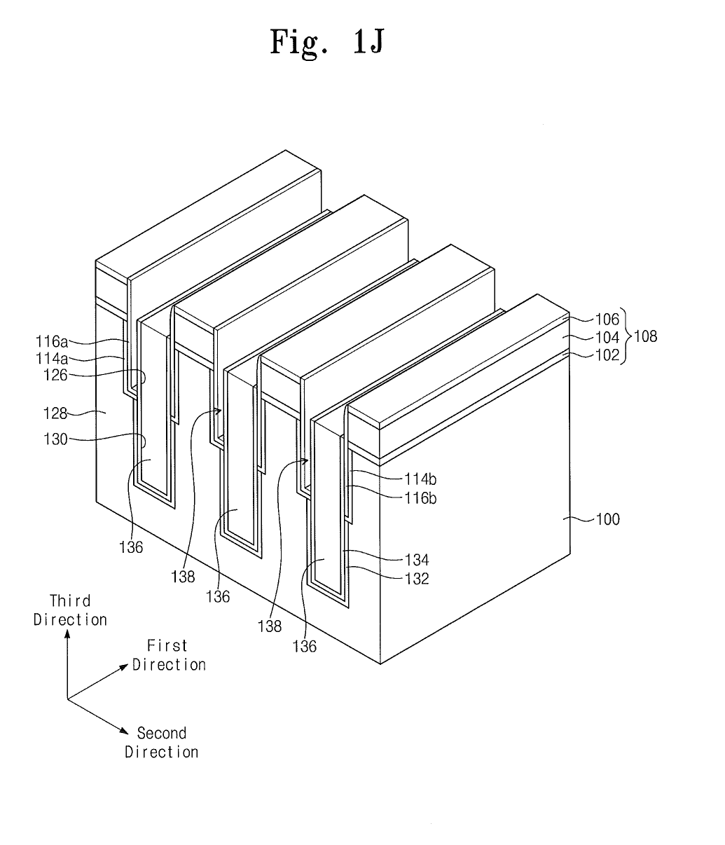

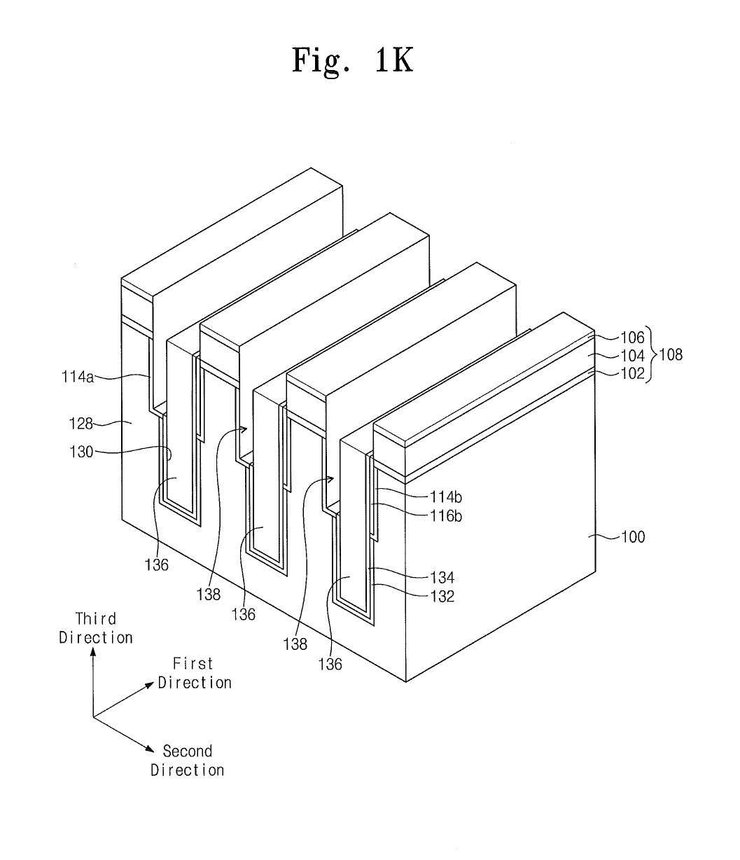

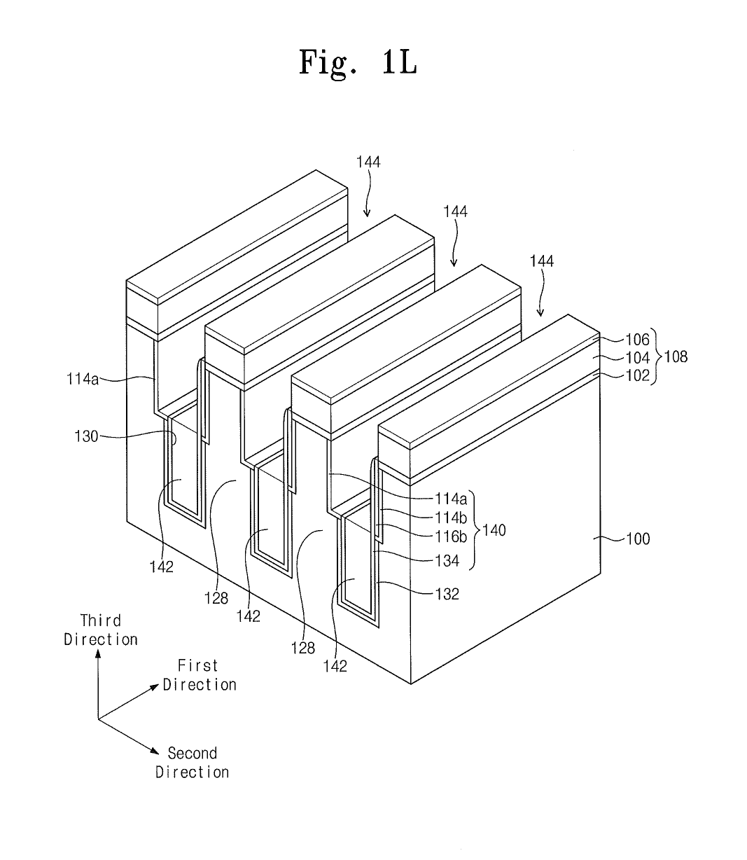

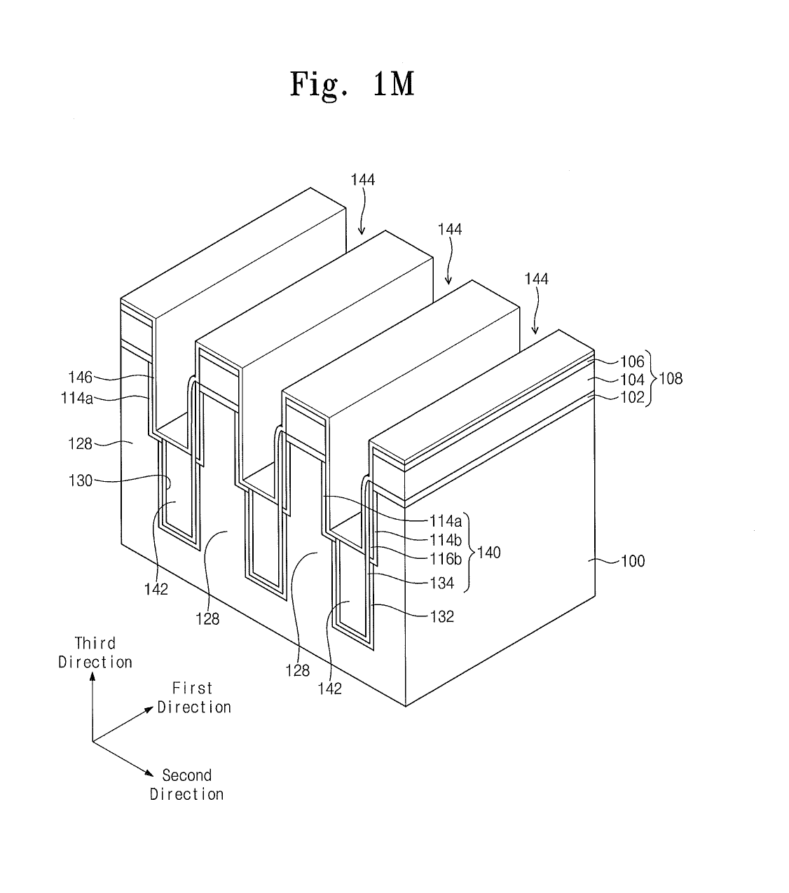

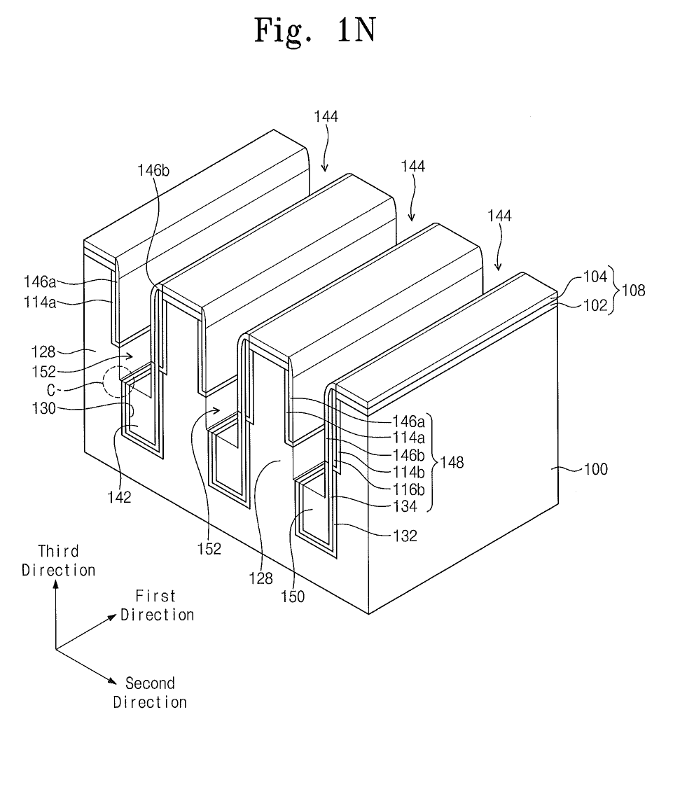

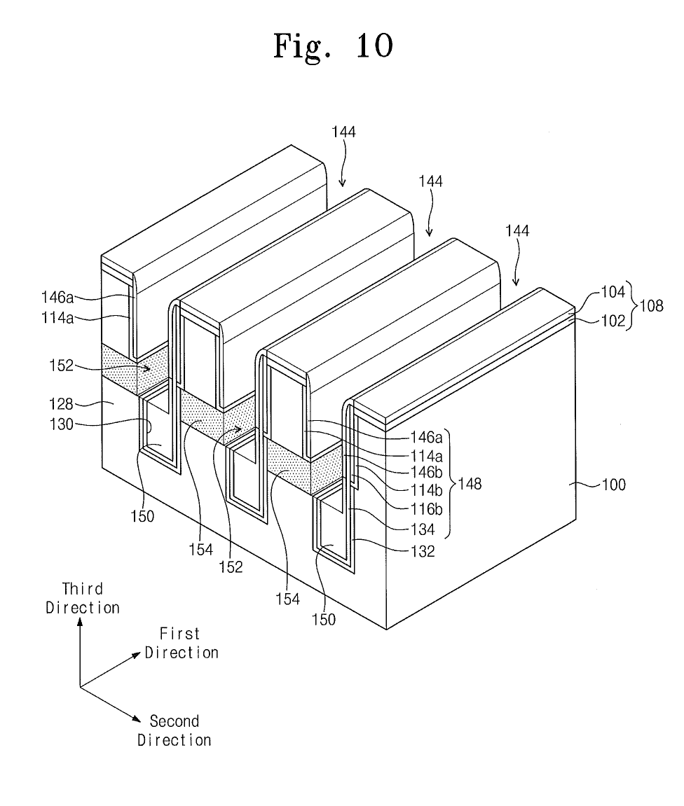

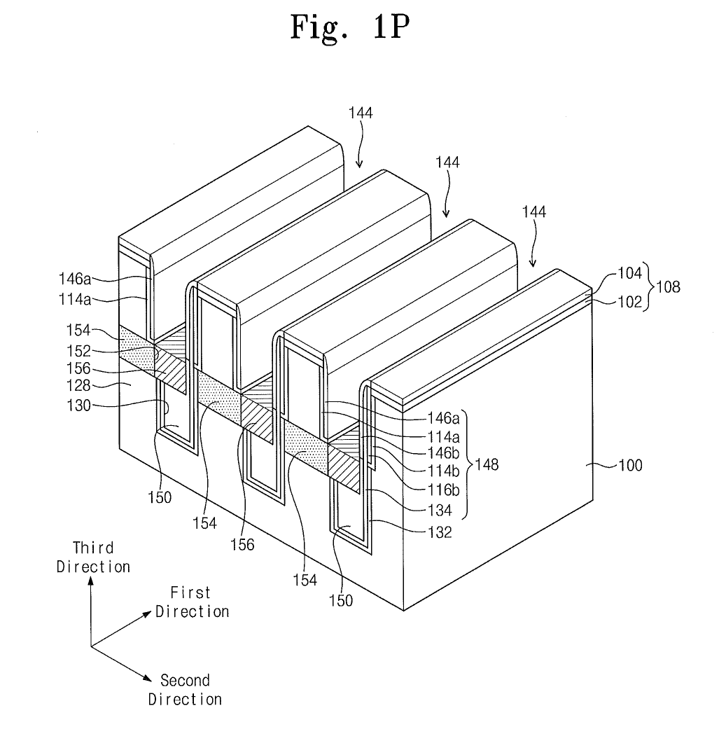

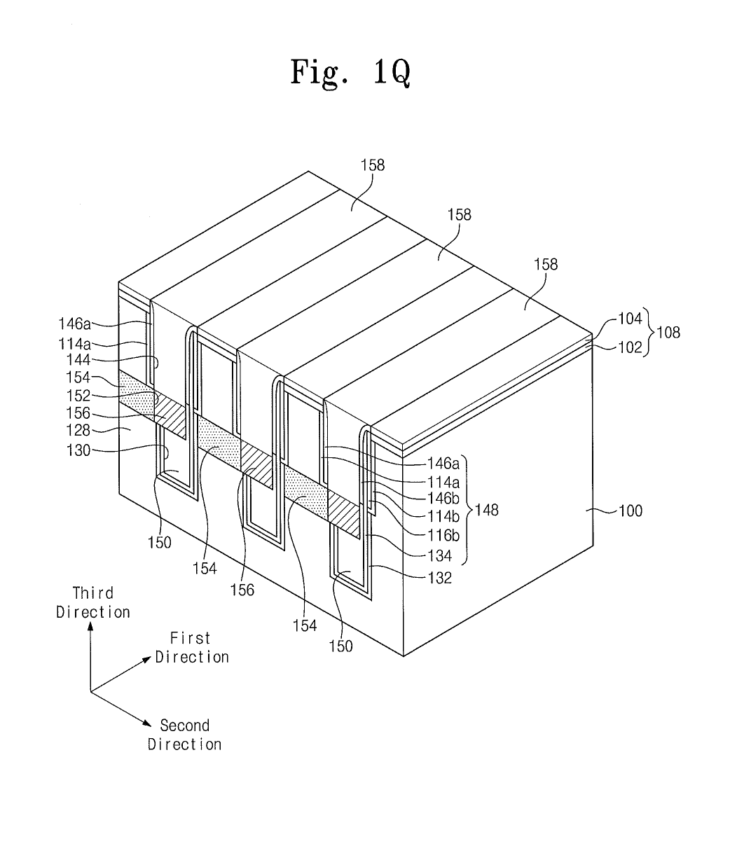

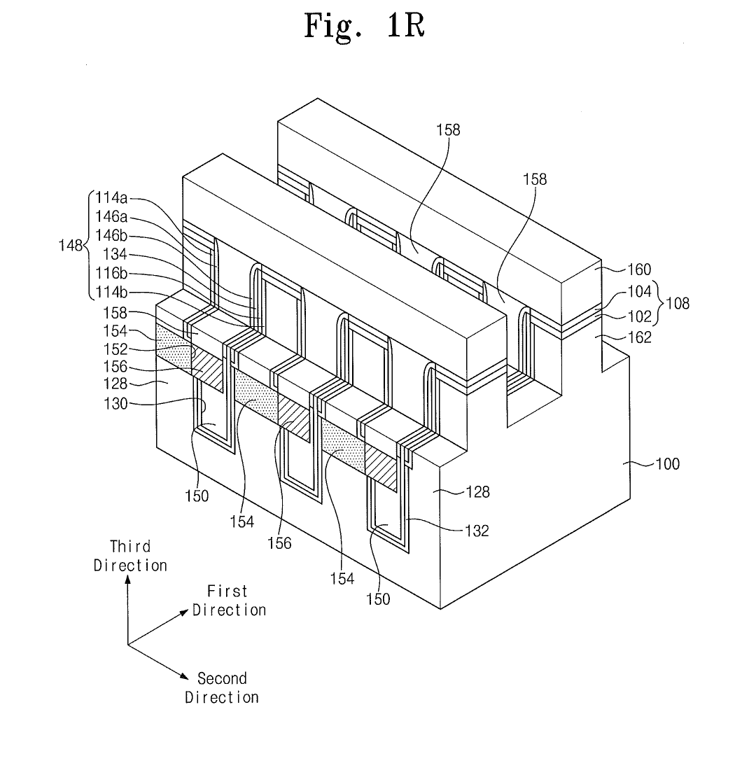

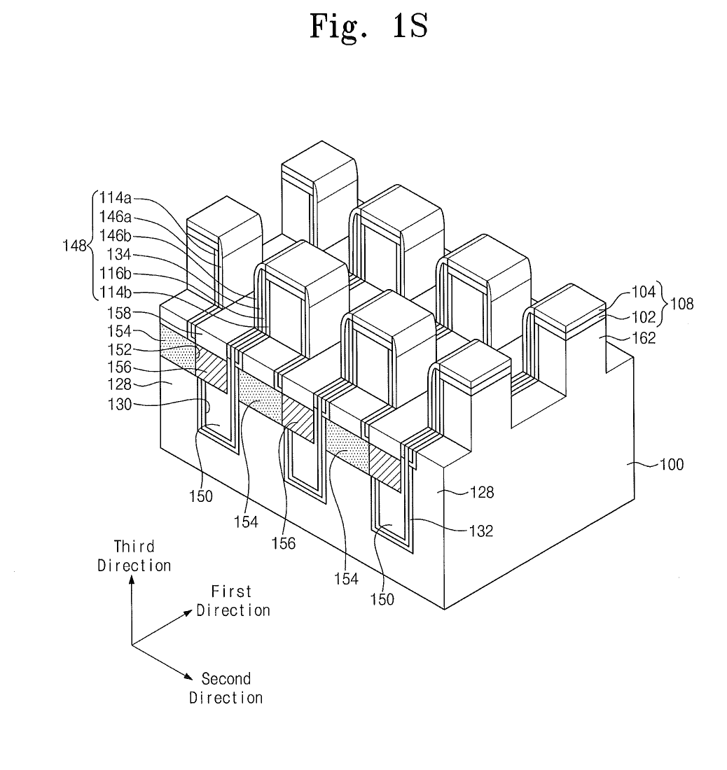

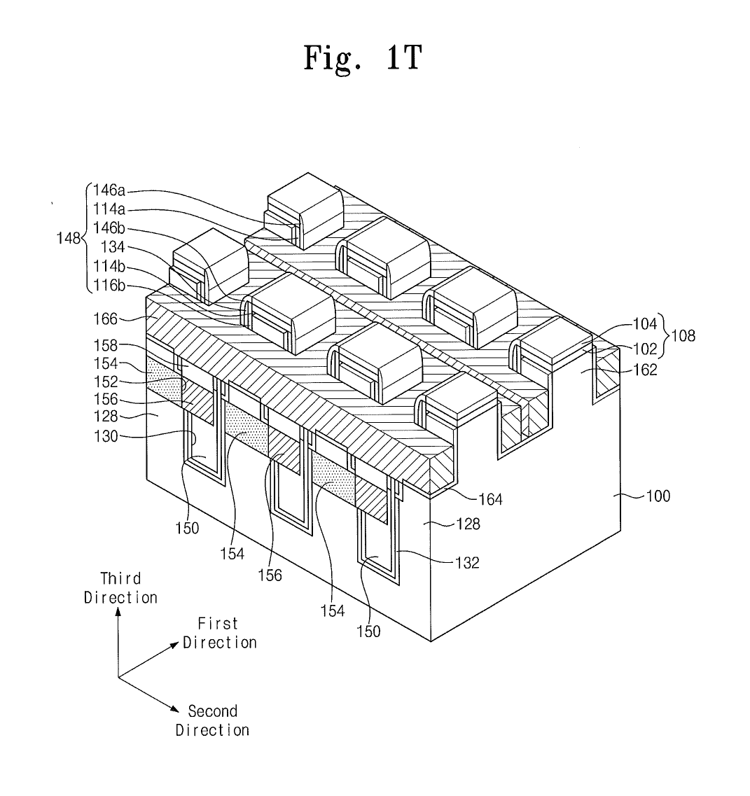

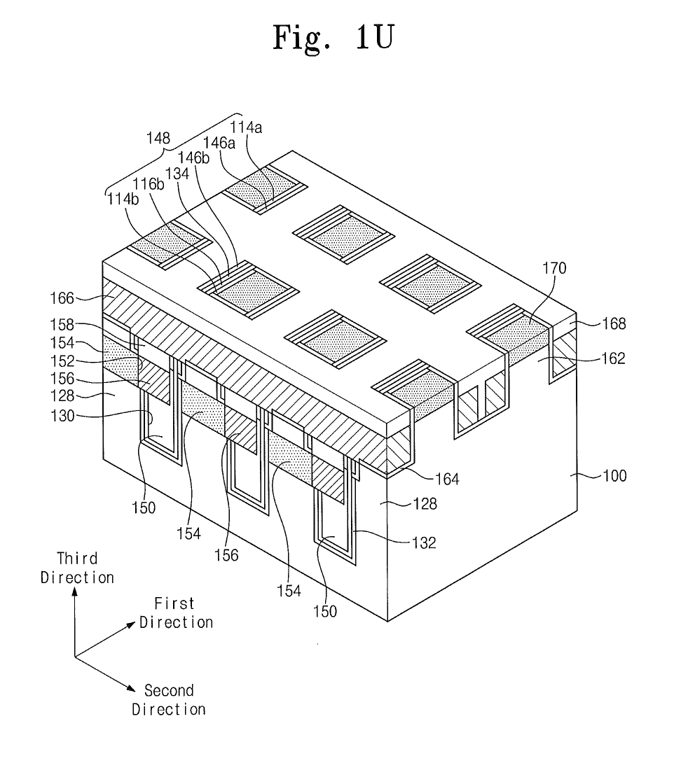

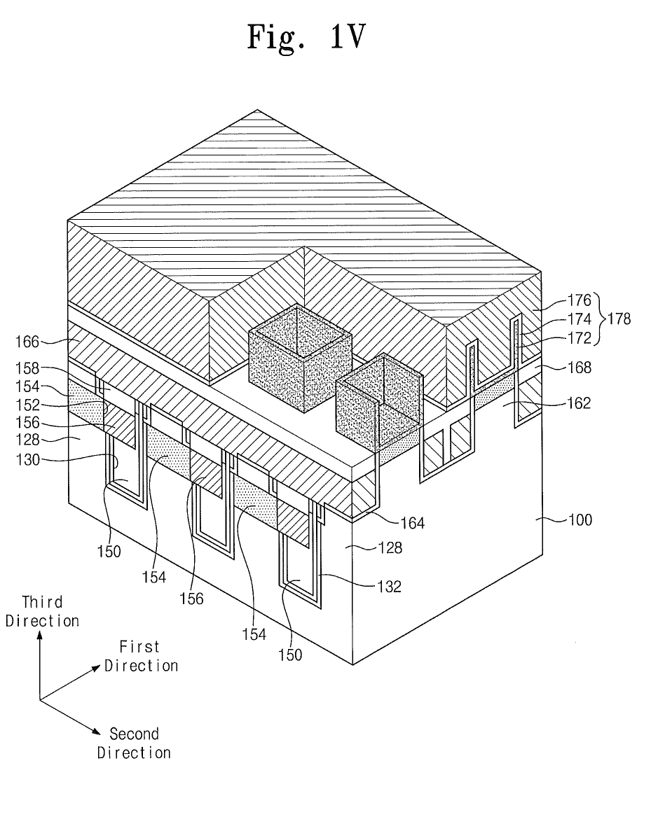

FIGS. 1A through 1V are perspective views illustrating a method of manufacturing a semiconductor device according to some embodiments of the inventive concept.

Referring to FIG. 1A, a preliminary first active pattern 110 may be formed in a substrate 100.

More specifically, a mask structure 108 may be formed on the substrate 100. The substrate 100 may be a semiconductor substrate such as a silicon substrate, a germanium substrate and a silicon-germanium substrate, a silicon-on-insulator (SOI) substrate, a germanium-on-insulator (GOI), a silicon-germanium-on-insulator (SGOI), etc.

According to some embodiments of the inventive concept, the mask structure 108 may be a multilayer structure. For instance, the mask structure 108 may have a structure in which an oxide pattern 102, a nitride pattern 104 and an oxide pattern 106 are sequentially stacked. Also, the mask structure 108 may extend in a first direction.

The substrate 100 may be etched by an etching process using the mask structure 108 to form the preliminary first active patterns 110 extending in the first direction. When the preliminary first active pattern 110 includes a plurality of patterns, a first opening 112 may be generated between the preliminary first active patterns 110. The first opening 112 may have a first width along a second direction. The first opening 112 may also extend in the first direction.

Referring to FIG. 1B, a first layer 116 may be conformally formed on the preliminary first active patterns 110 and the mask structure 108.

The first layer 116 does not bury the first opening 112 and may be continuously formed along a surface profile of the mask structure 108 and the preliminary first active pattern 110. According to some embodiments of the inventive concept, the first layer 116 may include a silicon nitride.

According to some embodiments, before forming the first layer 116, a first thermal oxide layer 114 may be formed on the substrate 100 exposed by the first opening 112. In the case that the substrate 100 includes silicon, the first thermal oxide layer 114 may be formed by performing a thermal oxidation on the substrate 100 exposed by the first opening 112. The first thermal oxide layer 114 does not bury the first opening 112 and may be formed along a surface profile of the substrate 100 exposed by the first opening 112.

Referring to FIG. 1C, a first spacer 118 may be formed on one sidewall of the preliminary first active pattern 110 on which the first layer 116 is formed and a second spacer 120 may be formed on the other sidewall of the preliminary first active pattern 110 on which the first layer 116 is formed.

More specifically, a spacer layer may be conformally formed on the first layer 116. The spacer layer may be continuously formed along a surface profile of the first layer 116 and may be formed so that the first opening 112 is not buried.

According to some embodiments of the inventive concept, the spacer layer may include a material having an etching selectivity with respect to the first layer 116. For example, in the case that the first layer 116 includes silicon nitride, the spacer layer may include metal nitride, for example, titanium nitride (TiN). However, the first layer 116 and the spacer layer are not limited to silicon nitride and metal nitride respectively.

The spacer layer is anisotropically etched to form the first spacer 118 and the second spacer 120 on one sidewall and the other sidewall of the preliminary first active pattern 110 on which the first layer 116 is formed, respectively.

Referring to FIG. 1D, a sacrificial layer 122 partly filling the first opening 112 may be formed on the mask structure 108. The sacrificial layer 122 may expose an upper portion of the first spacer 118. The first layer 116 formed on an upper portion of the mask structure 108 may be exposed together with the upper portion of the first spacer 118.

The sacrificial layer 122 may include a material having an etching selectivity with respect to the first and second spacers 118 and 120. The sacrificial layer 122 may also include a material having an etching selectivity with respect to the first layer 116.

According to some embodiments of the inventive concept, the sacrificial layer 122 may include silicon organic hybrid (SOH) material, metal, polysilicon, photoresist, polymer or oxide. The silicon organic hybrid may be, for example, silicon (H-SOC) including hydrogen and carbon, or silicon (C-SOC) including carbon. However, the sacrificial layer 122 of the inventive concept is not limited to those materials.

As an illustration, after partly etching the sacrificial layer 122, the mask structure 108 may be removed. As another illustration, after removing the first spacer 118 in a subsequent process, the mask structure 108 may be removed together with the sacrificial layer 122.

Referring to FIG. 1E, the first spacer 118 exposed by the sacrificial layer 122 may be selectively removed.

According to some embodiments of the inventive concept, a wet etching may be used to selectively remove the first spacer 118. A wet etching may use an etching solution substantially not etching the sacrificial layer 122 and the first layer 116 during a selective removal of the first spacer 118. The second spacer 120 covered by the sacrificial layer 122 may be protected from the etching process during a removal of the first spacer 118 exposed by the sacrificial layer 122.

A second opening 124 limited by the first layer 116 and the sacrificial 122 may be generated by removing the first spacer 118.

Referring to FIG. 1F, the sacrificial layer 122 may be removed.

According to some embodiments of the inventive concept, the sacrificial layer 122 may be removed by an ashing process. As described in FIG. 1D, the mask structure 108 may be removed during a removal of the sacrificial layer 122.

A third opening 126 exposing the second spacer 120 on one side may be generated by a removal of the sacrificial layer 122. The third opening 126 may have a second width along the second direction that is substantially smaller than the first width of the first opening 112. A difference between the first and second widths may be a thickness of the first layer 116.

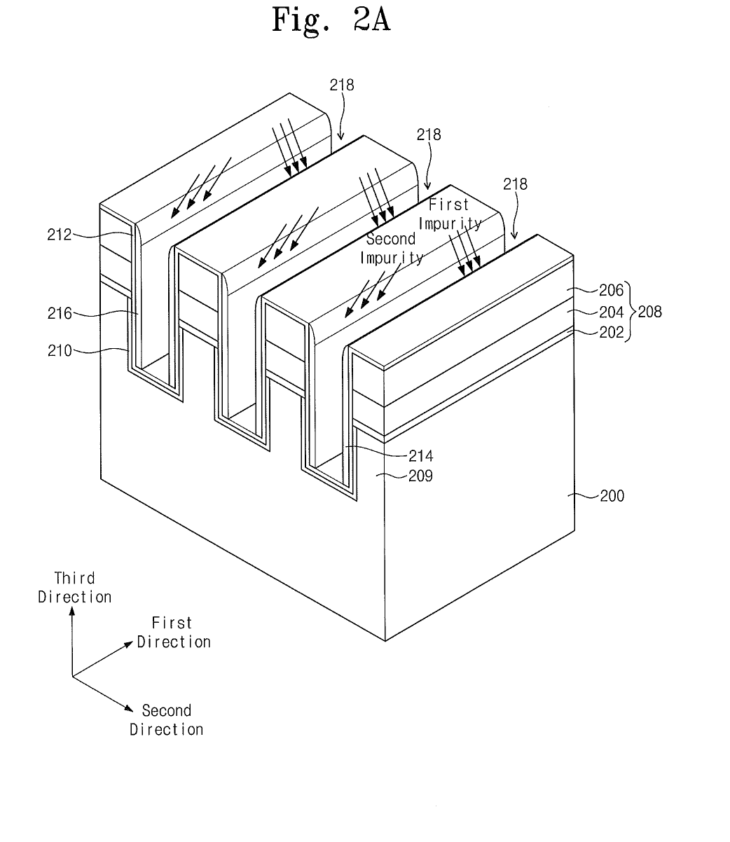

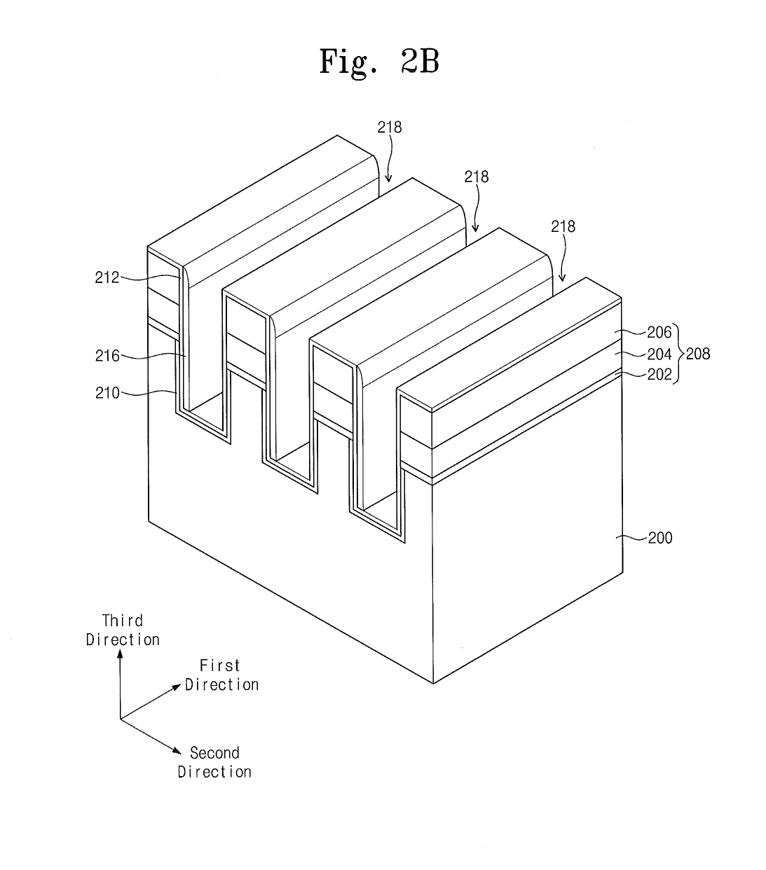

FIGS. 2A and 2B are perspective views illustrating a method of manufacturing the semiconductor device illustrated in FIG. 1F according to some embodiments of the inventive concept.

Referring to FIG. 2A, a first spacer 214 and a second spacer 216 may be formed on a substrate 200 on which a mask structure 208, a first thermal oxide layer 210, a preliminary first active pattern 209 and a first layer 212 are formed. Since a process of forming the mask structure 208, the first thermal oxide layer 210, the preliminary first active pattern 209, the first layer 212, the first spacer 214 and the second spacer 216 may be substantially the same as the process described in FIGS. 1A through 1C, it will be omitted. The first and second spacers 214 and 216 may include silicon.

A first impurity may be implanted into the first spacer 214 and a second impurity different from the first impurity may be implanted into the second spacer 216. The first spacer 214 including the first impurity and the second spacer 216 including the second impurity may have a substantially different etching selectivity.

Referring to FIG. 2B, the first spacer 214 may be selectively removed. Since the first spacer 214 includes the first impurity and the second spacer 216 includes the second impurity different from the first impurity, the first and second spacers 214 and 216 may have a different etching selectivity from each other. Therefore, the first spacer 214 may be selectively removed.

Thus, a structure in FIG. 1F may be manufactured according to FIGS. 2A and 2B.

Referring to FIG. 1G, the preliminary first active pattern 110 may be etched to form a first active pattern 128 from the preliminary first active pattern 110.

More specifically, a top surface and a bottom surface of the first layer 116 may be etched to respectively form first patterns 116a and 116b on both sidewalls of the preliminary first active pattern 110.

One 116b of the first patterns 116a and 116b may be on one sidewall of the preliminary first active pattern 110 and the other 116a of the first patterns 116a and 116b may be between the other sidewall of the preliminary first active pattern 110 and the second spacer 120.

According to some embodiments, in the case that the first thermal oxide layer 114 is formed, after the first patterns 116a and 116b are formed, a bottom surface of the first thermal oxide layer 114 may be exposed. The exposed first thermal oxide layer 114 is etched to form first thermal oxide patterns 114a and 114b on both sidewalls of the preliminary first active pattern 110. After forming the first thermal oxide patterns 114a and 114b, a surface of the substrate 100 under a bottom surface of the third opening 126 may be exposed.

The substrate 100 may be etched using the first pattern 116b formed on one sidewall of the preliminary first active pattern 110, the first pattern 116a formed on the other sidewall of the preliminary first active pattern 110 and the second spacer 120 as an etching mask to form a first active pattern 128 extending in the first direction. In the case that the first active pattern 128 includes a plurality of patterns, a trench 130 may be generated between the first active patterns 128. The trench 130 may extend in the first direction.

According to some embodiments of the inventive concept, the trench 130 may be formed by anisotropically etching the substrate 100. There may be a plasma etching process or a reactive ion etching (RIE) process as an example of an anisotropic etching. An upper portion of the mask structure 108 may be partly etched while forming the trench 130 by etching the substrate 100.

Also, the trench 130 may be formed under the third opening 126 while being connected to the third opening 126. The trench 130 may have the second width that is substantially the same as the third opening 126. When comparing the first opening 112 with the trench 130, the central axis of bottom surface of the first opening 112 may be different from the central axis of bottom surface of the trench 130. The central axis of bottom surface of the trench 130 may be located at a position spaced a width of the second spacer 120 apart from the central axis of bottom surface of the first opening 112.

Both sides of the first active patterns 128 may have different structures from each other at a connection portion of the trench 130 and the third opening 126. More specifically, one side of the first active pattern 128 may include a first vertical surface, a first horizontal surface and a second vertical surface. The other side of the first active pattern 128 may include a third vertical surface, a second horizontal surface and a fourth vertical surface. The first horizontal surface and the second horizontal surface may be formed to face toward each other at a connection portion of the trench 130 and the third opening 126. Widths of the first and second horizontal surfaces may be different from each other. As illustrated in FIG. 1G, a width of “A” part of the first active pattern 128 may be greater than a width of “B” part of the first active pattern 128. A width difference between the “A” part and the “B” part may be a width of the second spacer 120.

Referring to FIG. 1H, a second layer 134 may be conformally formed on the first active pattern 128 and the mask structure 108 including the first pattern 116a and the second spacer 120. The second layer 134 may be continuously formed along a surface profile of the first active pattern 128 and the mask structure 108 including the first pattern 116a and the second spacer 120. The second layer 134 may be formed so as not to fill the trench 130 and the third opening 126.

According to some embodiments of the inventive concept, the second layer 134 may include a material having an etching selectivity with respect to the second spacer 120. For example, in the case that the second spacer 120 includes metal nitride, the second layer 134 may include silicon nitride. However, the second layer 134 and the first and second spacers 118 and 120 of the inventive concept are not limited thereto.

According to some embodiments, before forming the second layer 134, a second thermal oxide layer 132 may be selectively and conformally formed on the first active pattern 128 limited by the trench 130. The second thermal oxide layer 132 may be continuously formed along an inner wall surface profile of the trench 130 so as not to fill the trench 130. The second thermal oxide layer 132 may be formed using a selective oxidation process, a thermal oxidation process or a chemical vapor deposition process.

Referring to FIG. 1I, a device isolation layer 136 may be formed that exposes an upper portion of the second spacer 120 on which the second layer 134 is formed.

More specifically, the device isolation layer 136 filling the third opening 126 and the trench 130 may be formed on the second layer 134. According to some embodiments of the inventive concept, the device isolation layer 136 may include a material having an etching selectivity with respect to the second spacer 120. The device isolation layer 136 may also include a material having an etching selectivity with respect to the second layer 134 and the mask structure 108. For example, in the case that the second spacer 120 includes metal nitride, the device isolation layer 136 may include an oxide. In this case, the mask structure 108 may include silicon nitride and a silicon oxide. However, the device isolation layer 136 and the second spacer 120 of the inventive concept are not limited thereto.

An upper portion of the device isolation layer 136 is partly etched to expose an upper portion of the second spacer 120 on which the second layer 134 is formed. The device isolation layer 136 may be partly etched by an etch-back process. An upper portion of the second layer 134 may be exposed by etching an upper portion of the device isolation layer 136. The exposed second layer 134 may be selectively etched. The second layer 134 is partly etched and thereby an upper portion of the second spacer 120 may be partly exposed.

According to some embodiments, the etched second layer 134 may be formed to surround the device isolation layer 136.

Referring to FIG. 1J, the exposed second spacer 120 may be removed.

According to some embodiments of the inventive concept, a wet etching may be used to selectively remove the second spacer 120. The wet etching may use an etching solution that may not substantially etch the device isolation layer 136 and the second layer 134 during a selective removal of the second spacer 120.

A fourth opening 138 may be generated by removing the second spacer 120 exposed by the device isolation layer 136. The fourth opening 138 may expose the first pattern 116a and a portion of the second layer 134. The first pattern 116b and the remaining second layer 134 may be covered by the device isolation layer 136. That is, the first pattern 116b and the second layer 134 formed on one side of the first active pattern 128 may be protected by the device isolation layer 136.

Referring to FIG. 1K, the first pattern 116a and the portion of second layer 134 exposed by the fourth opening 138 may be etched by an etch-back process. One side surface and a top surface of the device isolation layer 136 may be exposed by an etching process. The mask structure 108 may be exposed together with the device isolation layer 136. The first pattern 116b and the remaining second layer 134 may be covered by the device isolation layer 136.

Referring to FIG. 1L, an upper portion of the device isolation layer 136 is partly etched to form a preliminary device isolation pattern 142 filling the trench 130.

According to some embodiments, the device isolation layer 136 may be etched by a wet etching. A wet etching may use an etching solution that may not substantially etch the mask structure 108, the first pattern 116b and the second layer 134 while partly etching an upper portion of the device isolation layer 136.

Etching an upper portion of the device isolation layer 136 using a wet etching may reduce an etching damage of the mask structure 108 and may more easily perform an etching process compared with using a dry etching.

According to some embodiments of the inventive concept, in the case that the uppermost layer of the mask structure 108 includes an oxide and the device isolation layer 136 includes an oxide, the uppermost layer of the mask structure 108 may be etched while an upper portion of the device isolation layer 136 is partly etched.

By partly etching an upper portion of the device isolation layer 136, the preliminary device isolation pattern 142 filling the trench 130 is formed, but at the same time, a fifth opening 144 may be generated at an upper portion of the preliminary device isolation pattern 142. One side of the fifth opening 144 may expose the first thermal oxide pattern 114a and the other side of the fifth opening 144 may expose the second layer 134.

Hereinafter, the first thermal oxide pattern 114a formed on one side of the fifth opening 144, the first thermal oxide pattern 114b formed on the other side of the fifth opening 144, the first pattern 116b and the second layer 134 are called a preliminary sidewall mask 140.

Referring to FIG. 1M, a third layer 146 may be conformally formed on the mask structure 108, the preliminary sidewall mask 140 and the preliminary device isolation pattern 142.

The third layer 146 does not bury the fifth opening 144 and may be continuously formed along surfaces of the mask structure 108, the preliminary sidewall mask 140 and the preliminary device isolation pattern 142. According to some embodiments of the inventive concept, the third layer 146 may include silicon nitride.

Referring to FIG. 1N, third patterns 146a and 146b and a device isolation pattern 150 may be formed.

More specifically, a top surface and a bottom surface of the third layer 146 may be etched to form the third patterns 146a and 146b on both sidewalls of the fifth opening 144.

Hereinafter, the preliminary sidewall mask 140 and the third patterns 146a and 146b are together called a sidewall mask 148. The substrate 100 and the preliminary device isolation pattern 142 exposed to a bottom surface of the fifth opening 144 may be partly etched by an etching process using the sidewall mask 148. According to some embodiments of the inventive concept, an upper portion of the mask structure 108 may be partly etched during the etching process.

As a result of the etching process, the device isolation pattern 150 may be formed from the preliminary device isolation pattern 142. Also, a sixth opening 152 having a third width (along the second direction), which may be the same width as the fifth opening 144, may be generated at a lower portion of the fifth opening 144.

The device isolation pattern 150 may include a lower portion and an upper portion having a width substantially narrower than that of the lower portion. An upper portion width of the device isolation pattern 150 may have the same width as the width between the third patterns 146a and 146b of the sidewall mask 148. The device isolation pattern 150 may function as a field area. The device isolation pattern 150 may extend in the first direction, similar to the first active pattern 128.

Referring to “C” part of FIG. 1N, the first active pattern 128 may be exposed at a connection position of the fifth opening 144 and the sixth opening 152. More specifically, the first active pattern 128 may include a fifth vertical surface, a third horizontal surface and a sixth vertical surface. A portion of the fifth vertical surface and the third horizontal surface may be exposed. A width of the third horizontal surface may be the same as the widths of the third patterns 146a and 146b.

Referring to FIG. 1O, a first impurity region 154 may be formed by implanting an impurity into the substrate 100 exposed by the sixth opening 152.

The first impurity region 154 may be formed by performing an ion implantation process and a diffusion process. An ion implantation process may be performed on a surface of the substrate 100 to be inclined at a specific angle.

Referring to FIG. 1P, a buried first conductive pattern 156 filling the sixth opening 152 may be formed.

According to some embodiments of the inventive concept, the sixth opening 152 and the first conductive pattern 156 may be formed to be self aligned with each other. More specifically, the sixth opening 152 may be formed by an etching process using the sidewall mask 148, and the first conductive pattern 156 may be formed by filling the sixth opening 152 and may be self aligned with the device isolation pattern 150 and the first active pattern 128.

The first conductive pattern 156 may include silicon doped with an impurity, metal or metal compound. The first conductive pattern 156 may extend in the first direction. According to some embodiments of the inventive concept, the first conductive pattern 156 may function as a bit line of DRAM.

Referring to FIG. 1Q, a first interlayer insulating pattern 158 filling the fifth opening 144 may be formed on the first conductive pattern 156.

More specifically, a first interlayer insulating layer (not shown) filling the fifth opening 144 may be formed on the mask structure 108 and the first conductive pattern 156. The first interlayer insulating pattern 158 filling the fifth opening 144 may be formed by etching the first interlayer insulating layer so that a top surface of the mask structure 108 is exposed. A top surface of the first interlayer insulating pattern 158 may be substantially coplanar with a top surface of the mask structure 108.

Referring to FIG. 1R, a second mask 160 extending in the second direction may be formed on the first interlayer insulating pattern 158 and the mask structure 108. The second direction may be substantially different from the first direction. For instance, the second direction may be perpendicular to the first direction.

Through an etching process using the second mask 160, the mask structure 108 and the substrate 100 are partly etched to form second active patterns 162 having a polygonal shape or a cylindrical shape.

Also, an upper portion of the first interlayer insulating pattern 158 may be partly etched to be disposed between the second active patterns 162. At this time, the substrate 100 and the first interlayer insulating pattern 158 may be etched to a position where a top surface of the first conductive pattern 156 is not exposed.

The first interlayer insulating pattern 158 extends in the first direction and may include a lower portion formed between the first conductive pattern 156 and the first interlayer insulating pattern 158 and an upper portion formed between the second active pattern 162 and the first interlayer insulating pattern 158.

Each of the second active patterns 162 may be formed to protrude from the first active pattern 128 extending in the first direction. The protruding direction may be a third direction. The first conductive pattern 156 and the first interlayer insulating pattern 158 may be formed between the first active patterns 128 that extend in the first direction while also extending in the first direction.

According to some embodiments of the inventive concept, in the case that a horizontal cross section of the second active pattern 162 has a square shape, the sidewall mask 148 may be formed on a first side and a second side of the second active pattern 162. The first and second sides may be arranged in the second direction and may face toward each other. In the case that the substrate 100 includes silicon, the silicon may be exposed to a third side and a fourth side of the second active pattern 162. The third and fourth sides of the second active pattern 162 are arranged in the first direction and may face toward each other.

After forming the second active pattern 162, the second mask 160 may be removed.

Referring to FIG. 1S, an upper portion of the first interlayer insulating pattern 158 may be etched.

More specifically, a portion of the first interlayer insulating pattern 158 formed between the second active patterns 162 may be etched.

According to some embodiments of the inventive concept, an upper portion of the first interlayer insulating pattern 158 may be etched using a wet etching. The wet etching may use an etching solution that may not substantially etch the mask structure 108, the sidewall mask 148 and the substrate 100 while an upper portion of the first interlayer insulating pattern 158 is etched.

Referring to FIG. 1T, a gate insulating layer 164 may be selectively formed on the third and fourth sides of the second active pattern 162. The gate insulating layer 164 may be formed using a thermal oxidation process, a selective oxidation process or a chemical vapor deposition (CVD) process. According to some embodiments of the inventive concept, in the case that the second active pattern 162 includes silicon, the gate insulating layer 164 may include a silicon oxide formed by a thermal oxidation process.

A second conductive pattern 166 extending in the second direction may be formed while surrounding the second active pattern 162 on which the gate insulating layer 164 is formed. The second conductive pattern 166 may be formed while surrounding the adjacent second active patterns 162. Also, in the case that the second conductive pattern 166 includes a plurality of patterns, the second conductive patterns 166 may be parallel to one another and may formed to be spaced a predetermined distance apart from one another.

A top surface of the second conductive pattern 166 may be substantially lower than a top surface of the second active pattern 162. Thus, a part of upper portion of the second active pattern 162 may be exposed on which the sidewall mask 148 and the gate insulating layer 164 are formed.

According to some embodiments of the inventive concept, the second conductive pattern 166 may function as a gate electrode and may be embodied by a word line.

Referring to FIG. 1U, a second interlayer insulating pattern 168 may be formed on the second conductive pattern 166.

More specifically, a second interlayer insulating layer (not illustrated) may be formed to bury the second conductive pattern 166. An upper portion of the second interlayer insulating layer may be etched to expose the mask structure 108.

The exposed mask structure 108 and the second interlayer insulating layer may be continuously etched. The second interlayer insulating layer is etched while etching the mask structure 108 to expose a top surface of the second active pattern 162 and thereby the second interlayer insulating pattern 168 may be formed that is substantially coplanar with a top surface of the second active pattern 162.

Although not illustrated in detail in the drawing, a second impurity region 170 may be formed by implanting an impurity into an upper portion of the second active pattern 162 of which a top surface is exposed. The second impurity region 170 may function as a source/drain region together with the first impurity region 154 electrically connected to the first conductive pattern 156.

Referring to FIG. 1V, a capacitor 178 electrically connected to the second active pattern 162 may be formed.

The capacitor 178 may include a lower electrode 172, a dielectric layer 174 and an upper electrode 176. As an illustration, the lower electrode 172 of the capacitor 178 may have a polygonal pillar structure or a cylindrical structure. As another illustration, the capacitor 178 may have a planar structure in which the lower electrode 172, the dielectric layer 174 and the upper electrode 176 are sequentially stacked.

Although a DRAM was described as a semiconductor device by example, the present inventive concept is not limited thereto. As an example, a nonvolatile memory device may be embodied by forming a pattern including a phase change material instead of the second conductive pattern 166. As another example, a semiconductor device of the inventive concept may function as not only a memory device but also a logic device.

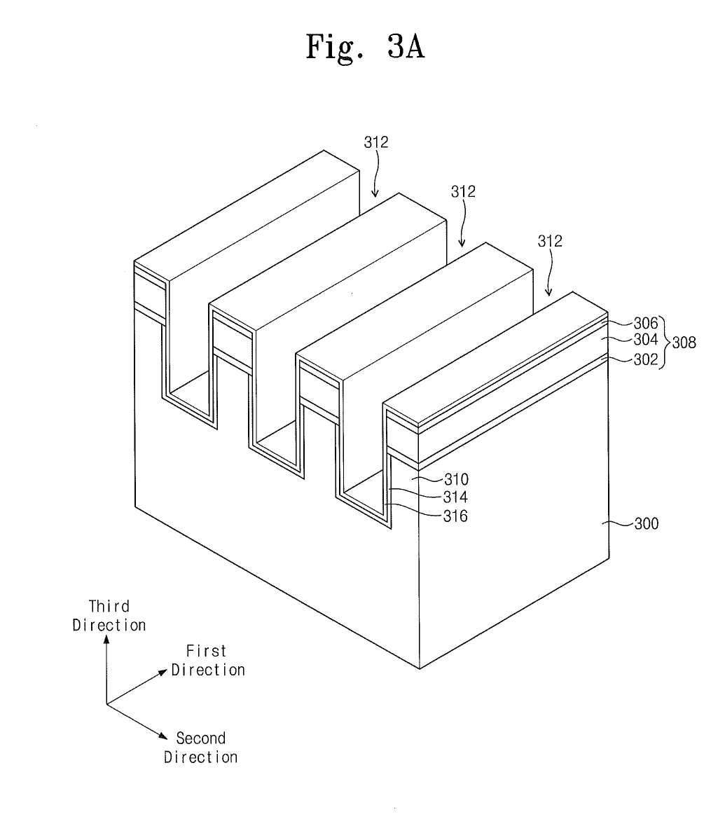

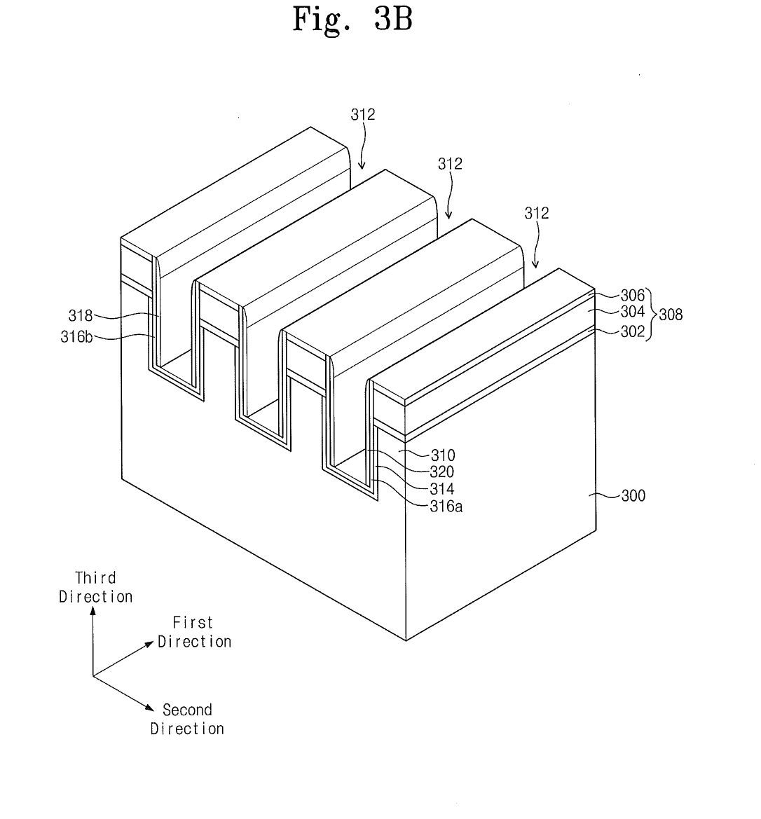

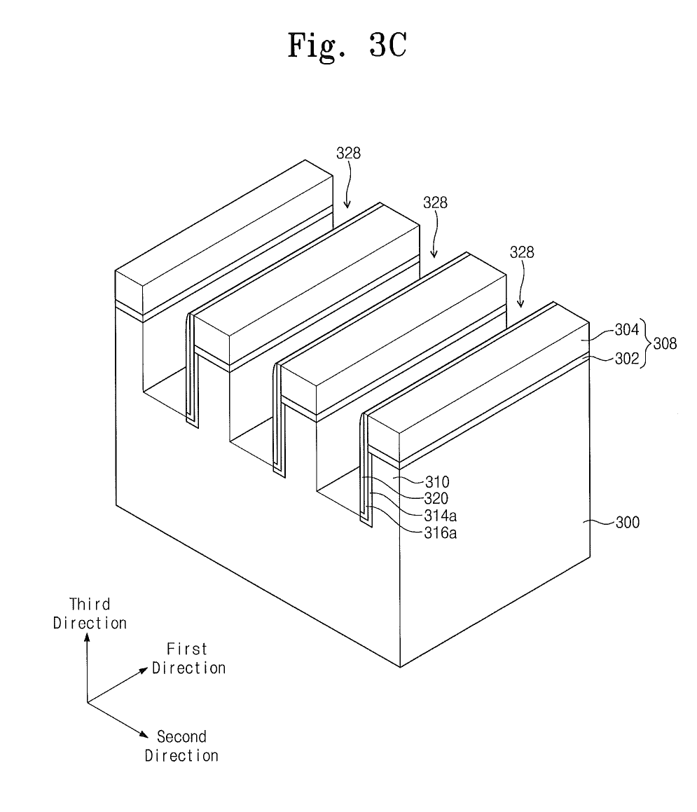

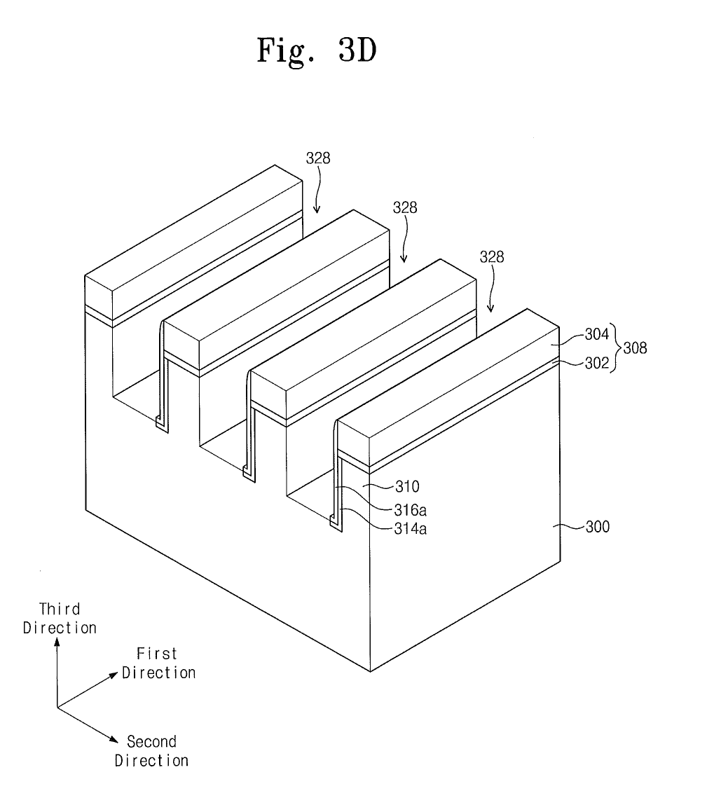

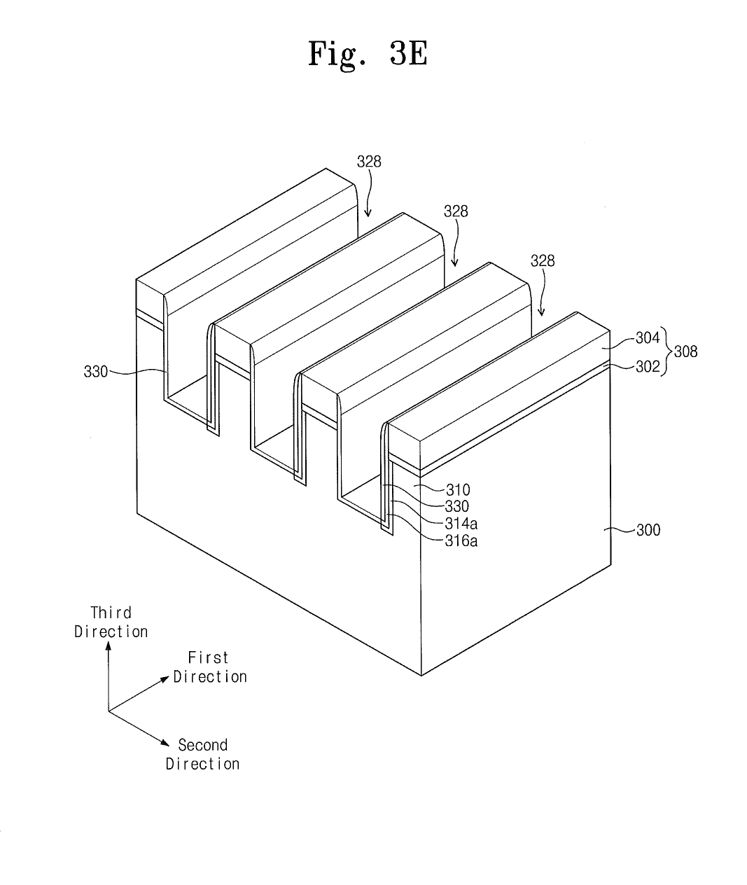

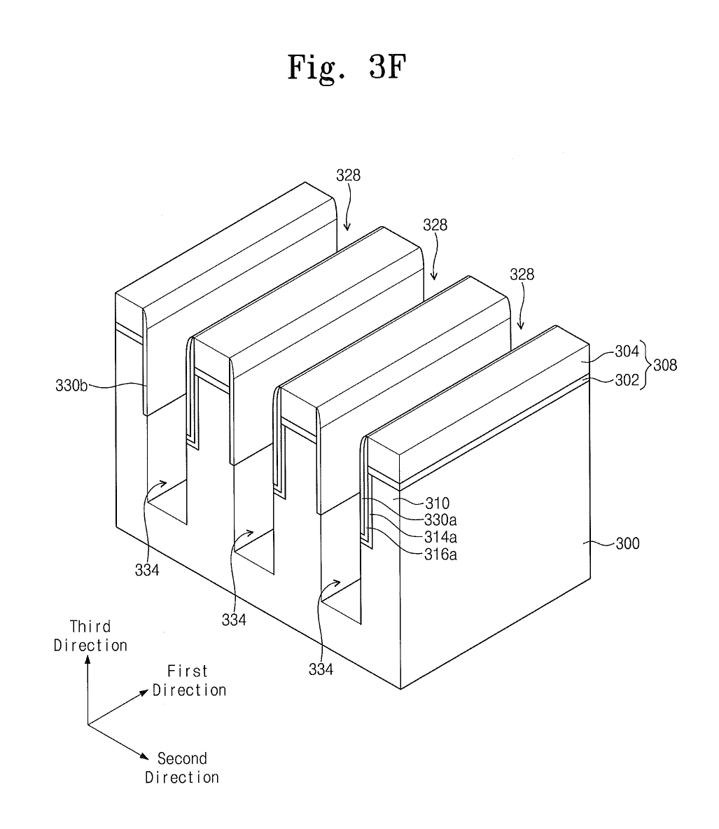

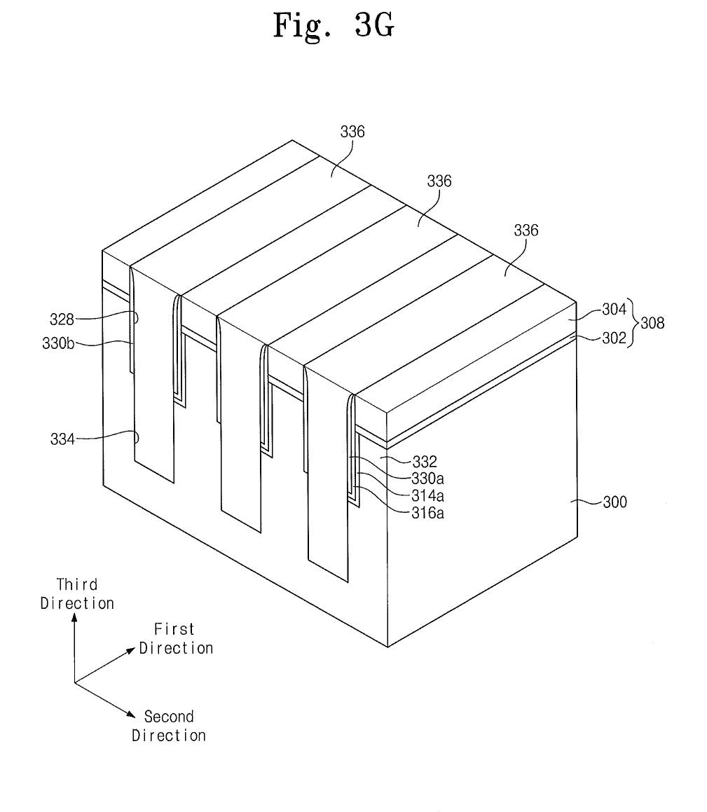

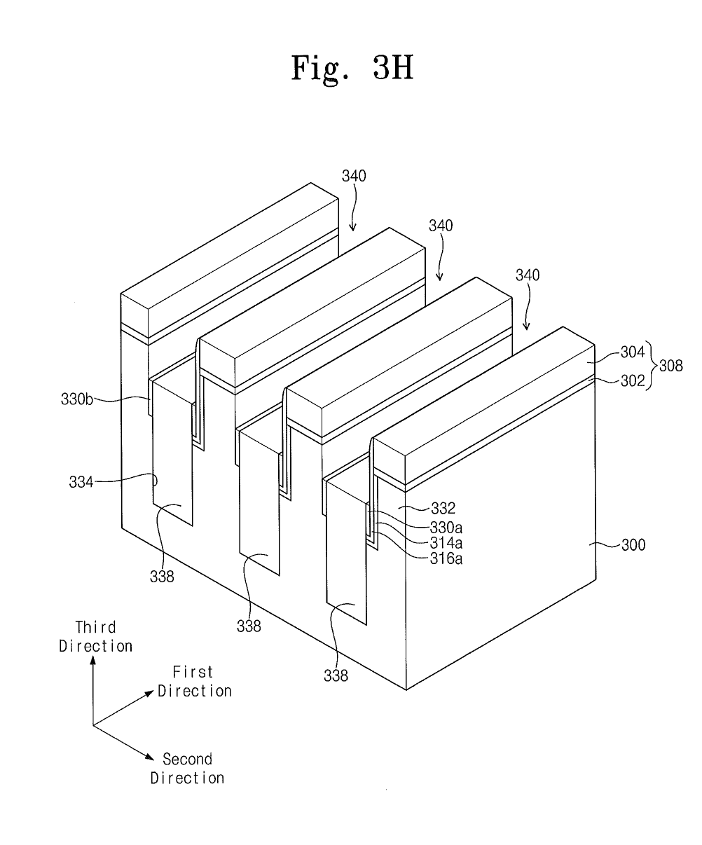

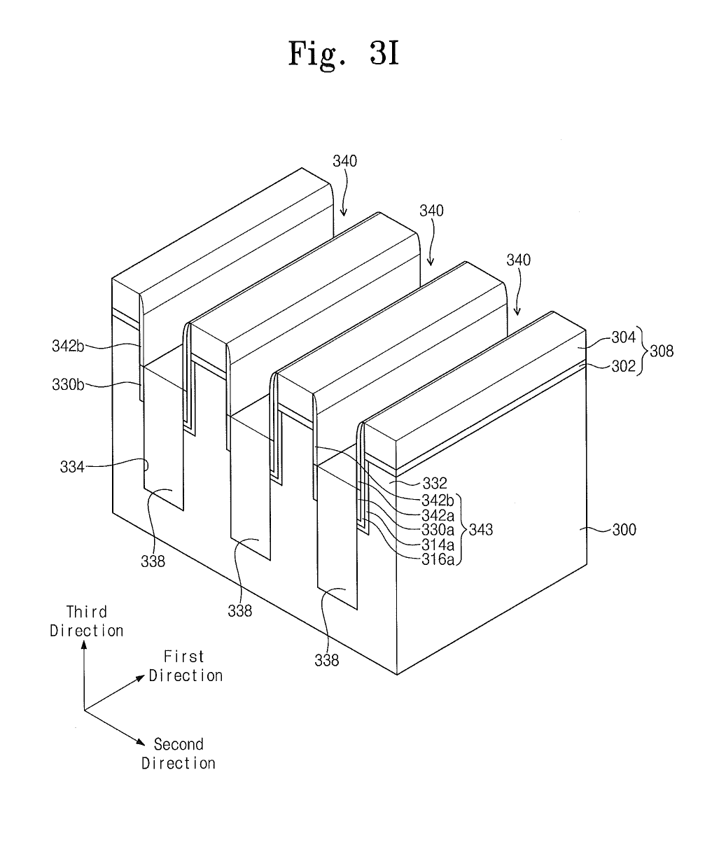

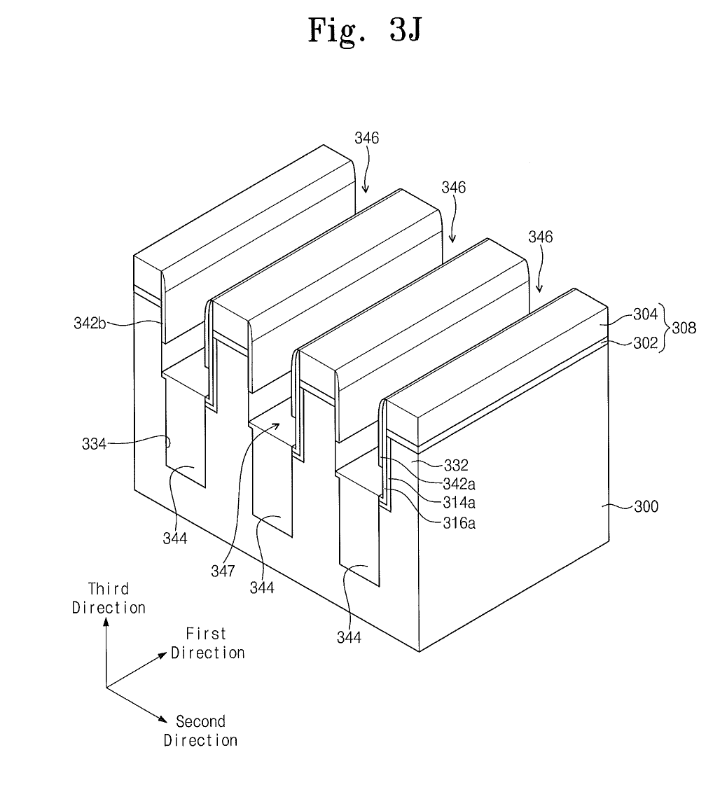

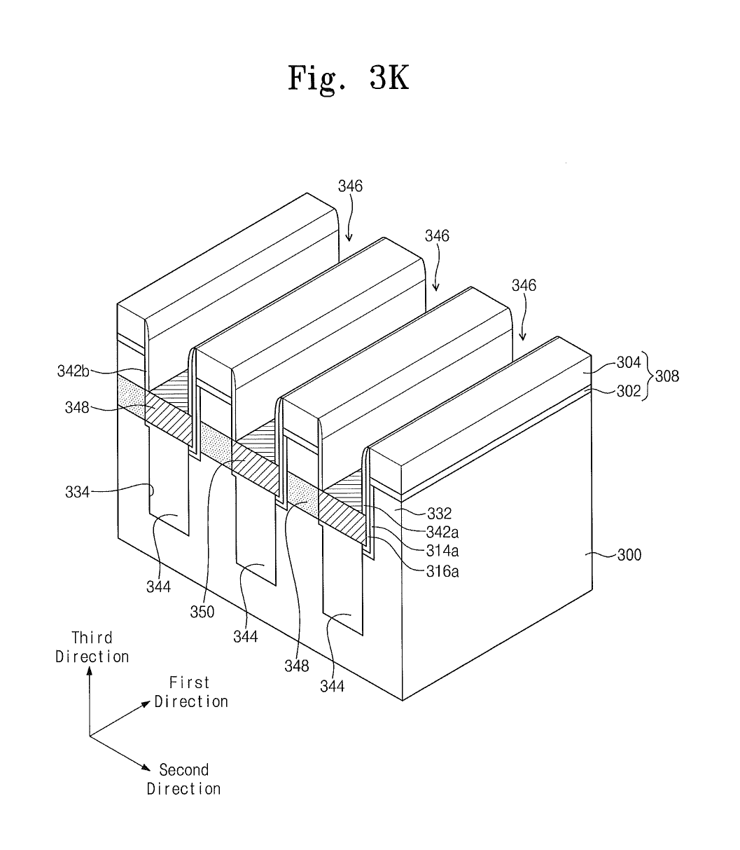

FIGS. 3A through 3K are perspective views illustrating a method of manufacturing a semiconductor device according to some embodiments of the inventive concept.

Referring to FIG. 3A, a mask structure 308, a preliminary first active pattern 310, a first thermal oxide layer 314 and a first layer 316 may be formed on a substrate 300. In the case that the preliminary first active pattern 310 includes a plurality of patterns, a first opening 312 may be generated between the preliminary first active patterns 310.

Referring to FIG. 3B, first and second spacers 318 and 320 may be respectively formed on inside walls of the first opening 312 on which the first layer 316 is formed. Since a process of forming the mask structure 308, the preliminary first active pattern 310, the first thermal oxide layer 314 and the first layer 316 and the first and second 318 and 320 may be substantially the same as that described in FIGS. 1A through 1C, a description of the process may be omitted.

Referring again to FIG. 3B, a top surface and a bottom surface of the first layer 316 exposed by the first and second spacers 318 and 320 may be selectively etched to form first patterns 316a and 316b.

One of the first patterns 316a and 316b may be formed on one side of the preliminary first active pattern 310 and may be formed between the first thermal oxide layer 314 and the first spacer 318. For example, the first pattern 316b may be formed on one side of the preliminary first active pattern 310 and may be formed between the first thermal oxide layer 314 and the first spacer 318. The other first pattern 316a may be formed on the other side of the preliminary first active pattern 310 and may be formed between the first thermal oxide layer 314 and the second spacer 320.

Referring to FIG. 3C, the first spacer 318 and the first pattern 316b formed on one side of the preliminary first active pattern 310 may be selectively removed. A second opening 328 may be generated by selectively removing the first spacer 318 and the first pattern 316b formed on one side of the preliminary first active pattern 310.

According to some embodiments of the inventive concept, a process of selectively removing the first spacer 318 and the first pattern 316b formed on one side of the preliminary first active pattern 310 may be the same as that described in FIGS. 1D through 1F. More specifically, the first spacer 318 and the first pattern 316b may be selectively removed using a sacrificial layer having an etching selectivity with respect to the first spacer 318. After removing the first spacer 318 and the first pattern 316b, the sacrificial layer may be removed. In the case that the sacrificial layer includes an oxide, the first thermal oxide layer 314 formed on one side of the preliminary first active pattern 310 may be partly etched during a removal of the sacrificial layer.

According to some embodiments of the inventive concept, a process of selectively removing the first spacer 318 and the first pattern 316b formed on one side of the preliminary first active pattern 310 may be the same as that described in FIGS. 2A and 2B. More specifically, the first and second spacers 318 and 320 may be formed to have an etching selectivity with respect to a specific etching solution by implanting different impurities into the first and second spacers 318 and 320 respectively. Using the method describe above, the first spacer 318 may be selectively removed, and then the first pattern 316b formed on one side of the preliminary first active pattern 310 may be removed. In this case, a first thermal oxide layer 314a formed on the preliminary first active pattern 310 may not be removed.

Referring to FIG. 3D, the second spacer 320 may be selectively removed.

Since the second spacer 320 includes a material having an etching selectivity with respect to the first pattern 316a, the first pattern 316a may remain on the other side of the preliminary first active pattern 310 during a removal of the second spacer 320. Also, the first oxide layer 314a formed under the first pattern 316a may not be etched by the first pattern 316a.

As a result, one side of the preliminary first active pattern 310 may be exposed and the first thermal oxide layer 314a and the first pattern 316a may be formed on the other side of the preliminary first active pattern 310.

Referring to FIG. 3E, a second thermal oxide layer 330 may be conformally formed on one side of the preliminary first active pattern 310, the substrate 300 exposed by the second opening 328 and the other side of the preliminary first active pattern 310 on which the first thermal oxide layer 314a and the first pattern 316a are formed.

The second thermal oxide layer 330 may not bury the second opening 328 and may be continuously formed on one side of the preliminary first active pattern 310, the substrate and the first pattern 316a. The second thermal layer 330 may be formed by a chemical vapor deposition (CVD) process or an atomic layer deposition (ALD) process.

Referring to FIG. 3F, the preliminary first active pattern 310 may be etched to form a first active pattern 332 from the preliminary first active pattern 310.

More specifically, a top surface and a bottom surface of the second thermal oxide layer 330 may be selectively etched to form second thermal oxide patterns 330a and 330b on one side of the preliminary first active pattern 310 and the other side of the preliminary first active pattern 310 on which the first thermal oxide layer 314a and the first pattern 316a are formed, respectively.

The substrate 300 exposed by the second opening 328 may be etched using the second thermal oxide pattern 330b formed on one side of the preliminary first active pattern 310 and first thermal oxide layer 314a, the first pattern 316a and the second thermal oxide pattern 330a formed on the other side of the preliminary first active pattern 310 as an etching mask to form the first active pattern 332.

In the case that the first active pattern 332 includes a plurality of patterns, a trench 334 may be formed between the first active patterns 332. The trench 334 may extend in a first direction that is the substantially same as an extension direction of the first active pattern 332. The trench 334 may be generated to be connected to the second opening 328 under the second opening 328.

Referring to FIG. 3G, a device isolation layer 336 burying the second opening 328 and the trench 334 may be formed on the mask structure 308.

According to some embodiments of the inventive concept, the device isolation layer 336 may include an oxide. The device isolation layer 336 formed on the mask structure 308 may be planarized down to a top surface of the mask structure 308. As an example of a planarization process, there may be an etch-back process and/or a chemical mechanical polishing (CMP) process.

Referring to FIG. 3H, an upper portion of the device isolation layer 336 may be partly etched so that an upper portion of the first active pattern 332 is exposed and thereby a preliminary device isolation pattern 338 may be formed.

According to some embodiments of the inventive concept, in the case that the device isolation layer 336 includes an oxide, an upper portion of the second thermal oxide patterns 330a and 330b may be partly etched while the preliminary device isolation pattern 338 is formed by etching an upper portion of the device isolation layer 336. A lower portion of the second thermal oxide patterns 330a and 330b may remain on a sidewall of the first active pattern 332.

As a result of an etching process, a third opening 340 may be generated on an upper portion of the preliminary device isolation pattern 338. An upper portion of one side surface of the first active pattern 332 is exposed and the first thermal oxide layer 314a and the first pattern 316a may be formed on an upper portion of the other side surface of the first active pattern 332. Also, the second thermal oxide pattern 330b may be formed on a lower portion of one side surface of the preliminary device isolation pattern 338 and the second thermal oxide pattern 330a may be formed on a lower portion of the other side surface of the preliminary device isolation pattern 338.

Referring to FIG. 3I, second patterns 342a and 342b may be respectively formed on an upper portion of one side surface of the first active pattern 332 and the other side surface of the first active pattern 332 on which the first thermal oxide layer 314a and the first pattern 316a are formed.

More specifically, a second layer (not illustrated) may be conformally formed on an upper portion of one side surface of the first active pattern 332, the preliminary device isolation pattern 338 exposed to a bottom surface of the third opening 340 and an upper portion of the other side surface of the first active pattern 332 on which the first thermal oxide layer 314a and the first pattern 316a are formed. The second layer may not bury the third opening 340 and may be continuously formed on an upper portion of one side surface of the first active pattern 332, the preliminary device isolation pattern 338 and the first pattern 316a.

The second layer may include a material having an etching selectivity with respect to the second thermal oxide patterns 330a and 330b and the preliminary device isolation pattern 338. According to some embodiments of the inventive concept, in the case that the second thermal oxide patterns 330a and 330b and the preliminary device isolation pattern 338 include an oxide, the second layer may include nitride. For instance, the second layer may include silicon nitride.

By etching a top surface and a bottom surface of the second layer, second patterns 342a and 342b may be respectively formed on an upper portion of one side surface of the first active pattern 332 and an upper portion of the other side surface of the first active pattern 332 on which the first thermal oxide layer 314a and the first pattern 316a are formed.

Therefore, a sidewall mask 343 may be formed on one side and the other side of the first active pattern 332. The sidewall mask 343 may include the second pattern 342b formed on one side of the first active pattern 332 and the first thermal oxide layer 314a, the first pattern 316a and the second pattern 342a formed on the other side of the first active pattern 332.

Referring to FIG. 3J, an upper portion of the preliminary device isolation pattern 338 may be etched by an etching process using the sidewall mask 343 to form a device isolation pattern 344 burying the trench 334.

According to some embodiments of the inventive concept, in the case that the preliminary device isolation pattern 338 includes an oxide, the second thermal oxide patterns 330a and 330b may be etched together while an upper portion of the preliminary device isolation pattern 338 is etched. An upper portion of the preliminary device isolation pattern 338 and the second thermal oxide patterns 330a and 330b may be etched by a wet etching. The wet etching may use an etching solution such that the sidewall mask 343 is not substantially etched while an upper portion of the preliminary device isolation pattern 338 and the second thermal oxide patterns 330a and 330b are etched. For example, in the case that the preliminary device isolation pattern 338 and the second thermal oxide patterns 330a and 330b include an oxide and the first and second patterns 316a, 342a and 342b of the sidewall mask 343 include nitride, an etching solution of the wet etching may have a high etching rate with respect to an oxide and may have a low etching rate with respect to nitride.

A height of a top surface of the device isolation pattern 344 may become different according to an etching degree of an upper portion of the preliminary device isolation pattern 338.

As a result of an etching, a lower portion of one side surface of the first active pattern 332 may be exposed and the second pattern 342b may be formed on an upper portion of one side surface of the first active pattern 332. The first pattern 316a and the first thermal oxide layer 314a may be formed on a lower portion of the other side surface of the first active pattern 332 and the second pattern 342a, the first pattern 316a and the first thermal oxide layer 314a may be formed on an upper portion of the other side surface of the first active pattern 332. Also, a fourth opening 346 defined by an upper portion of the first active pattern 332 and a fifth opening 347 defined by the lower portion of the first active pattern 332 and connected to the fourth opening 346 may be generated. A width of the fifth opening 347 may be greater than a width of the fourth opening 346.

Referring to FIG. 3K, after forming a first impurity region 348 by implanting an impurity into the first active pattern 332 exposed by the fifth opening 347, a first conductive pattern 350 burying the fifth opening 347 may be formed.

According to some embodiments of the inventive concept, the first conductive pattern 350 burying the fifth opening 347 may be formed to be self aligned. More specifically, the fifth opening 347 may be formed by an etching process using the sidewall mask 343 and the first conductive pattern 350 formed while burying the fifth opening 347 may be self aligned with the device isolation pattern 344 and the first active pattern 332.

Although not illustrated in detail, a gate insulating layer, a gate electrode, a second conductive pattern, a second impurity region and a capacitor may be formed through a subsequent process. The description thereof may be substantially the same as that described in FIGS. 1Q through 1V and thereby it is omitted.

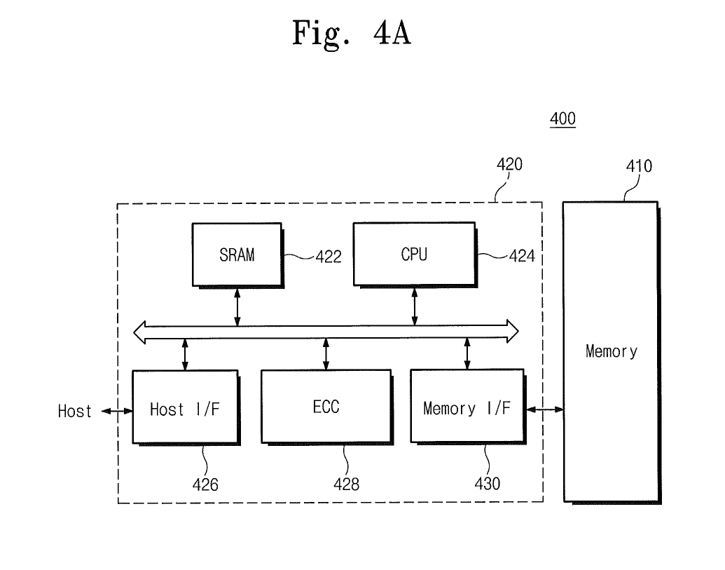

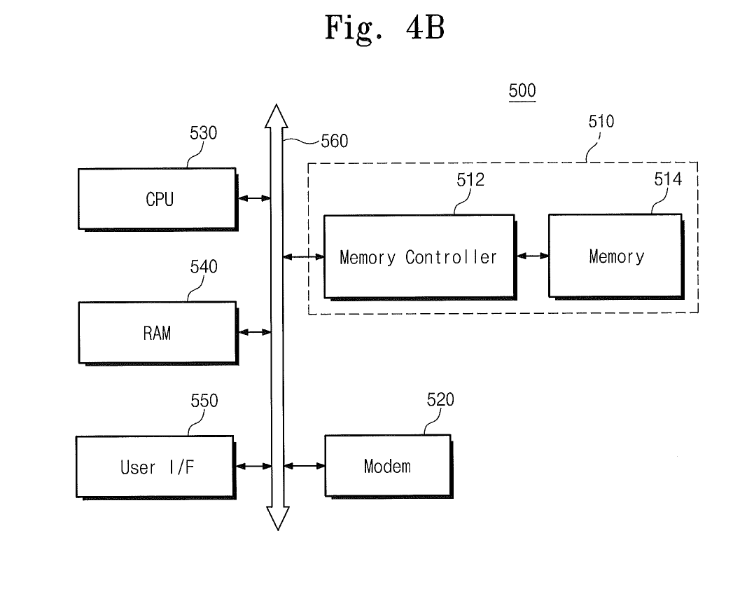

FIG. 4A is a block diagram illustrating a system including a memory device according to some embodiments of the inventive concept. Although a memory device is described in some embodiments of the inventive concept as an illustration, a non-memory device may alternatively be used as a semiconductor device.

Referring to FIG. 4A, a semiconductor device in accordance with some embodiments of the inventive concept may be applied to a memory card 400. As an illustration, the memory card 400 may include a memory controller 420 controlling all data exchanges between a host and a memory 410. A static random access memory (SRAM) 422 may be used as an operation memory of a central processing unit (CPU) 424. A host interface 426 may include a data exchange protocol of the host connected to the memory card 400. An error correction code 428 can detect and correct an error included in data read out from the memory 410. A memory interface 430 interfaces with the memory 410. The central processing unit (CPU) 424 performs all the control operations for data exchange of the memory controller 420.

A semiconductor device in accordance with some embodiments of the inventive concept may be applied to the memory 410 of the memory card 400. A process of forming a buried type bit line in accordance with some embodiments of the inventive concept may have an improved/superior process margin compared with a process using a general photomask. Thus, a semiconductor device may be more easily and efficiently manufactured.

FIG. 4B is a block diagram illustrating an information processing system with a memory according to some embodiments of the inventive concept.

Referring to FIG. 4B, an information processing system 500 may include a memory system 510 including a semiconductor memory device in accordance with some embodiments of the inventive concept. The information processing system 500 may include a mobile device or a computer. As an example, the information processing system 500 may include the memory system 510 and a modem 520, a central processing unit (CPU) 530, a RAM 540 and a user interface 550 that are electrically connected to a system bus 560. The memory system 510 may store data processed by the central processing unit (CPU) 530 or data received from the outside. The memory system 510 may include a memory 514 and a memory controller 512 and may be constituted to be the substantially same as the memory card 400 described with reference to FIG. 4A. The information processing system 500 may be provided to a memory card, a solid state disk, a camera image processor and an application chipset. As an illustration, the memory system 510 may be constituted by a solid state disk and in this case, the information processing system 500 can stably and reliably store large amounts of data in the memory system 510.

According to some embodiments of the inventive concept, a limitation of photoresist patterning process may be overcome by forming a buried conductive pattern using a sidewall mask without an etching process of a photoresist pattern.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents. Therefore, the above-disclosed subject matter is to be considered illustrative, and not restrictive.

What is claimed is:

1. A semiconductor device comprising:
first active patterns extending in a direction;
second active patterns each having a pillar shape that protrudes from an upper portion of each of the first active patterns;
a device isolation pattern between each of the first active patterns;
a sidewall mask extending from a side surface of each of the first active patterns along a side surface of each of the second active patterns; and
a buried conductive pattern on the device isolation pattern between the first active patterns and extending in the direction, one side surface of the buried conductive pattern being in contact with one of the first active patterns.

2. The semiconductor device of claim 1, wherein the device isolation pattern includes a lower portion having a first width and an upper portion upwardly extending from one side of the lower portion and having a second width substantially smaller than the first width.

3. The semiconductor device of claim 2, wherein a side surface of the buried conductive pattern that opposes the one side surface of the buried conductive pattern is in contact with an upper portion of the device isolation pattern.

4. The semiconductor device of claim 2, wherein the sidewall mask includes a first portion on ones of sidewalls of the first and second active patterns and a second portion on ones of opposing sidewalls of the first and second active patterns and wherein a thickness of the first portion is substantially smaller than a thickness of the second portion.

5. The semiconductor device of claim 4, wherein the first and second portions of the sidewall mask are on opposing side surfaces of the buried conductive pattern.

6. The semiconductor device of claim 2, wherein a central axis of a bottom surface of the buried conductive pattern is offset from a central axis of a bottom surface of the device isolation pattern.

7. The semiconductor device of claim 1,
wherein a central axis of a bottom surface of the buried conductive pattern is located at a same axis line as a central axis of a bottom surface of the device isolation pattern, and
wherein the sidewall mask includes a third portion on ones of sidewalls of the first and second active patterns and a fourth portion on ones of opposing sidewalls of the first and second active patterns, and wherein a thickness of the third portion is substantially smaller than a thickness of the fourth portion.

8. The semiconductor device of claim 7, wherein the third and fourth portions of the sidewall mask are on opposing side surfaces of the buried conductive pattern.

9. The semiconductor device of claim 7, wherein a width of the buried conductive pattern is substantially greater than a width of the device isolation pattern.

10. A method of manufacturing a semiconductor device comprising:
forming preliminary first active patterns extending in a first direction on a substrate;
forming a sidewall mask on upper sidewalls of the preliminary first active patterns;
forming first active patterns extending in the first direction and second active patterns each having a pillar shape on the first active patterns by partly etching the preliminary first active patterns in a second direction different from the first direction;
forming a device isolation pattern between the first active patterns under the sidewall mask; and
forming a buried conductive pattern on the device isolation pattern by an etching process using the sidewall mask, one side surface of the buried conductive pattern being in contact with one of the first active patterns.

11. The method of claim 10, wherein while partly etching the preliminary first active patterns in the second direction, the sidewall mask substantially remains on the sidewalls of the first and second active patterns.

12. The method of claim 10, wherein forming the buried conductive pattern includes;
forming first and second spacers on opposing sidewalls of the preliminary first active patterns;
removing the first spacer;
forming the first active patterns and a trench by etching the substrate using the second spacer as an etching mask;
forming first patterns on opposing sidewalls of the first active patterns;
forming a preliminary device isolation pattern burying the trench;
removing the second spacer;
forming the device isolation pattern by etching the first active patterns and a preliminary device isolation pattern using the first patterns as an etching mask; and
forming the buried conductive pattern in an opening defined by the device isolation pattern and the first active patterns.

13. The method of claim 12, wherein removing the first spacer includes:
forming a sacrificial layer exposing the first spacer while burying a space between the preliminary first active patterns on which the first and second spacers are formed; and
removing the exposed first spacer,
wherein the first and second spacers and the sacrificial layer are formed from a material having a different etching selectivity with respect to an etching solution used in etching the first active patterns.

14. The method of claim 12, wherein removing the first spacer includes:
after forming the first and second spacers, making the first and second spacers have a different etching selectivity from each other with respect to an etching solution by implanting a first impurity into the first spacer and a second impurity into the second spacer; and
removing the first spacer using the etching solution.

15. The method of claim 10, wherein forming the sidewall mask includes:
forming first and second parts of the sidewall mask on opposing sidewalls of the preliminary first active patterns,
wherein a thickness of the first part of the sidewall mask is substantially smaller than a thickness of the second part of the sidewall mask.

16. A semiconductor device comprising:
first and second active patterns, the second active patterns protruding from the first active patterns;
a sidewall mask having first and second portions on opposing sidewalls of the first active patterns and on opposing sidewalls of the second active patterns, the first portion of the sidewall mask having a plurality of layers and having a greater width than the second portion of the sidewall mask;
a device isolation pattern between the sidewalls of the first active patterns;
a buried conductive pattern on the device isolation pattern; and
an insulating layer on the buried conductive pattern and between the first and second portions of the sidewall mask.

17. The semiconductor device of claim 16, wherein at least a portion of the device isolation pattern is between opposing sidewalls of an oxide pattern.

18. The semiconductor device of claim 16, wherein the first portion of the sidewall mask includes a layer that the second portion of the sidewall mask does not include.

19. The semiconductor device of claim 16, wherein a protruding portion of the device isolation pattern protrudes along one sidewall of the buried conductive pattern, the protruding portion of the device isolation pattern having a width that is substantially aligned with, and substantially equal to, a width of one of the plurality of layers of the first portion of the sidewall mask.

20. The semiconductor device of claim 16, wherein at least a portion of the buried conductive pattern is recessed within the sidewall mask.
